(19) United States
(12) Patent Application Publication
(10) Pub. No.: US 2026/0173510 A1
(43) Pub. Date: Jun. 18, 2026

(54) SEMICONDUCTOR DEVICE

(71) Applicant: Samsung Electronics Co., Ltd., Suwon-si (KR)

(72) Inventors: Youngki Lee, Suwon-si (KR); Inhyun Song, Suwon-si (KR); Keun Hwi Cho, Suwon-si (KR)

(21) Appl. No.: 19/263,348

(22) Filed: Jul. 8, 2025

(30) Foreign Application Priority Data
Dec. 13, 2024 (KR) 10-2024-0186060

(51) Int. Cl. H10D 84/83; H01L 23/522; H01L 23/528; H10D 30/00; H10D 30/01; H10D 30/43; H10D 62/10; H10D 62/13; H10D 64/23; H10D 84/01

(52) U.S. Cl. CPC H10D 84/832; H10D 30/43; H10D 30/502; H10D 62/121; H10D 62/151; H10D 64/256; H10W 20/42; H10W 20/435; H10D 30/014; H10D 30/019; H10D 84/0149; H10D 84/0153

(57) ABSTRACT

A semiconductor device may comprise a substrate including first and second surfaces facing each other, and having a first region including conductive impurities and a second region, a channel pattern spaced apart along a first direction on the first surface, a first source/drain pattern positioned on the first region and second source/drain patterns connected to both sides of the channel pattern and positioned on the second region, a gate structure surrounding the channel pattern and extending in a second direction intersecting the first direction, a separation structure penetrating the gate structure positioned on both sides of the first source/drain pattern, and a lower wiring structure positioned on the second surface of the substrate, wherein the first region and the second region include different materials.

### CROSS-REFERENCE TO RELATED APPLICATION

This application claims priority to and the benefit of Korean Patent Application No. 10-2024-0186060 filed with the Korean Intellectual Property Office on Dec. 13, 2024, the entire contents of which are incorporated herein by reference.

### BACKGROUND

The manufacturing process of semiconductor devices is complex due to higher integration and higher performance. These processes include plasma-based processes such as etching, deposition, and cleaning. The plasma process is carried out in a state where high-energy ions, electrons, and neutral particles are mixed, which enables high-precision processing.

Plasma processes may cause physical and chemical damage to semiconductor devices and surrounding structures. For example, high-energy particles included in plasma may cause deterioration of gate oxide films, metal wiring, and insulating films. Additionally, charge accumulation generated by plasma may degrade the electrical properties of the device and, in severe cases, lead to device failure.

Therefore, effectively protecting semiconductor devices during the plasma process while maintaining process efficiency is desired.

### SUMMARY

The present disclosure relates to a semiconductor device having improved characteristics.

A semiconductor device according to some embodiments may include a substrate having a first surface and a second surface that face each other, and including a first region including conductive impurities and a second region, a channel pattern spaced apart along a first direction on the first surface, a first source/drain pattern positioned on the first region and second source/drain patterns connected to both sides of the channel pattern and positioned on the second region, a gate structure surrounding the channel pattern and extending in a second direction intersecting the first direction, a separation structure penetrating the gate structure positioned on both sides of the first source/drain pattern, and a lower wiring structure positioned on the second surface of the substrate, wherein the first region and the second region may include different materials.

A semiconductor device according to some embodiments may include a substrate having a first surface and a second surface that face each other, and including a first region including conductive impurities and a second region, a lower pattern extending in a first direction on the first surface, a plurality of channel patterns stacked and spaced apart from each other on the lower pattern, a first source/drain pattern positioned on the first region and second source/drain patterns connected to both sides of the channel pattern and positioned on the second region, a gate structure surrounding the channel pattern and extending in a second direction intersecting the first direction, a separation structure penetrating the gate structure positioned on both sides of the first source/drain pattern, and a lower wiring structure positioned on the second surface of the substrate, wherein the first region and the second region may include different materials.

A semiconductor device according to some embodiments may include a substrate having a first surface and a second surface that face each other, a first region including conductive impurities, a second region including an insulating material, and a third region in which passive elements are positioned, a channel pattern spaced apart from each other in a first direction on the first surface of the substrate, a first source/drain pattern positioned on the first region and second source/drain patterns connected to both sides of the channel pattern and positioned on the second region, a gate structure extending in a second direction intersecting the first direction and surrounding the channel pattern, a separation structure penetrating the gate structure positioned on both sides of the first source/drain pattern, and a lower wiring structure positioned on the second surface of the substrate, wherein the first region and the third region may include a same material, and the first region and the second region may include different materials.

According to embodiments of the present disclosure, it is possible to prevent deterioration of electrical characteristics of a semiconductor device by preventing charge accumulation in the semiconductor device.

### BRIEF DESCRIPTION OF THE DRAWINGS

FIG. 1 is a top plan view illustrating a semiconductor device according to an embodiment.

FIG. 2 is a cross-sectional view taken along line A-A′ of FIG. 1 according to an embodiment.

FIG. 3 is a cross-sectional view taken along line B-B′ of FIG. 1 according to an embodiment.

FIG. 4 is a cross-sectional view taken along line C-C′ of FIG. 1 according to an embodiment.

FIG. 5 is a cross-sectional view taken along line A-A′ of FIG. 1 according to another embodiment.

FIG. 6 is a cross-sectional view taken along line B-B′ of FIG. 1 according to another embodiment.

FIG. 7 is a cross-sectional view taken along line A-A′ of FIG. 1 according to another embodiment.

FIG. 8 is a cross-sectional view taken along line C-C′ of FIG. 1 according to another embodiment.

FIG. 9 is a cross-sectional view taken along line A-A′ of FIG. 1 according to another embodiment.

FIG. 10 is a top plan view showing a semiconductor device according to another embodiment.

FIG. 11 is a cross-sectional view taken along line D-D′ of FIG. 10 according to an embodiment.

FIG. 12 is a cross-sectional view taken along line E-E′ of FIG. 10 according to an embodiment.

FIG. 13 is a cross-sectional view taken along line F-F′ of FIG. 10 according to an embodiment.

FIG. 14 is a cross-sectional view taken along line D-D′ of FIG. 10 according to another embodiment.

FIG. 15 is a cross-sectional view taken along line D-D′ of FIG. 10 according to another embodiment.

FIG. 16 is a cross-sectional view taken along line D-D′ of FIG. 10 according to another embodiment.

FIGS. 17, 18, 19, 20, 21, 22, 23, 24, 25, 26, and 27 are cross-sectional views illustrating a method for manufacturing a semiconductor device according to an embodiment.

### DETAILED DESCRIPTION

Hereinafter, various embodiments of the present disclosure will be described in detail with reference to the attached drawings so that a person having ordinary skill in the art to which the present disclosure pertains may easily implement the disclosure. The present disclosure may be embodied in many different forms and is not limited to the embodiments described herein.

In order to clearly explain the present disclosure, portions that are not directly related to the present disclosure may be omitted, and the same reference numerals are attached to the same or similar constituent elements throughout the entire specification.

In addition, the size and thickness of each component shown in the drawing are arbitrarily shown for better understanding and ease of description, so the present disclosure is not necessarily limited to what is shown.

To clearly represent the various layers and areas in the drawing, the thickness is enlarged and shown. And in the drawing, for better understanding and ease of description, the thickness of some layers and areas is exaggerated.

It will be understood that when an element such as a layer, film, region, or substrate is referred to as being “on” another element, it may be directly on the other element or intervening elements may also be present. In contrast, when an element is referred to as being “directly on” another element, there are no intervening elements present. Also, being “above” or “on” a reference part means being positioned above or below the reference part, and does not necessarily mean being positioned “above” or “on” the opposite direction of gravity.

In addition, unless explicitly described to the contrary, the word “comprise”, and variations such as “comprises” or “comprising”, will be understood to imply the inclusion of stated elements but not the exclusion of any other elements.

Additionally, throughout the specification, when we state “in plan”, we mean when the target portion is viewed from above, and when we say \“in cross section\”, we mean when the target portion is viewed from the side in a cross-section cut vertically.

Additionally, throughout the specification, two directions parallel to and intersecting with the upper surface of the substrate are defined as a first direction D1 and a second direction D2, respectively, and the direction perpendicular to the upper surface of the substrate is described as a third direction D3. For example, the first direction D1 and the second direction D2 may be orthogonal to each other.

In the drawings, a semiconductor device according to some embodiments may include a GAA (Gate All Around) and MBCFET™ (Multi-Bridge Channel Field Effect Transistor) including nanowires or nanosheets are illustrated, but the present disclosure is not limited thereto. According to an embodiment, the semiconductor device may include a fin-type transistor (FinFET) including a channel region in a fin-type pattern shape, a tunneling transistor (tunneling FET), a 3D-SFET (3D Stack Field Effect Transistor) structure, and a CFET (Complementary Field Effect Transistor) structure.

Hereinafter, a semiconductor device according to an embodiment will be described with reference to the drawings.

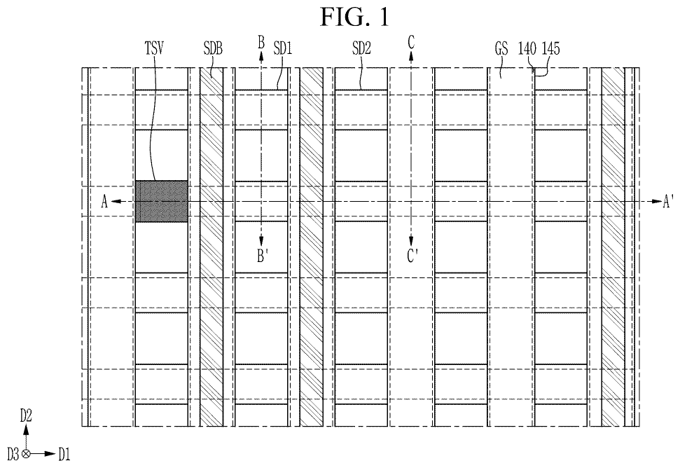

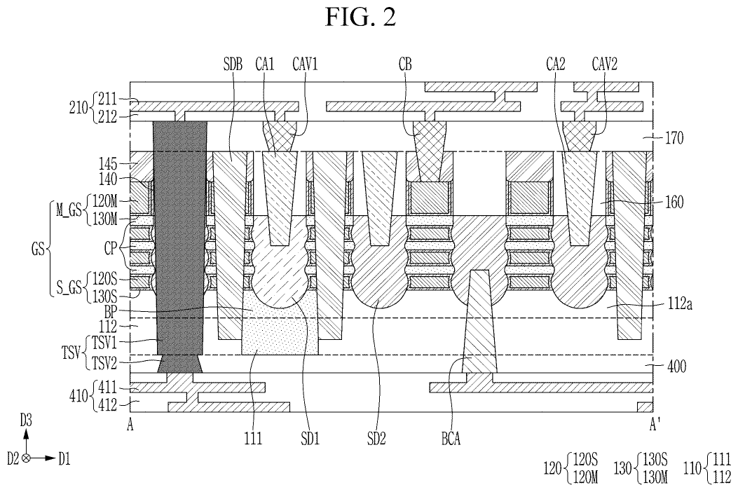

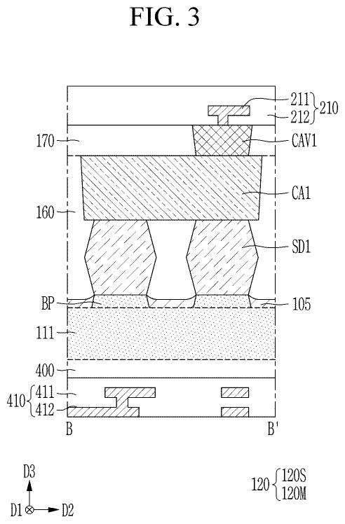

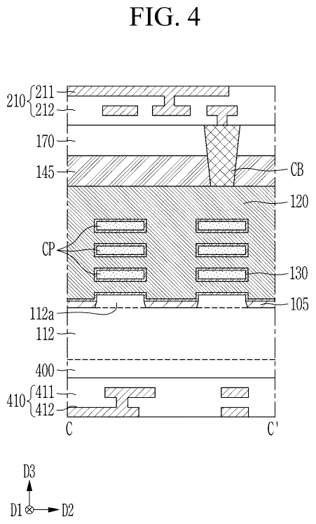

FIG. 1 is a top plan view illustrating a semiconductor device according to an embodiment. FIG. 2 is a cross-sectional view taken along line A-A′ of FIG. 1 according to an embodiment. FIG. 3 is a cross-sectional view taken along line B-B′ of FIG. 1 according to an embodiment. FIG. 4 is a cross-sectional view taken along line C-C′ of FIG. 1 according to an embodiment.

Referring to FIGS. 1 to 4, a semiconductor device according to an embodiment may include a substrate 110, a separating structure SDB, channel patterns CP, first and second source/drain patterns SD1 and SD2, gate structures GS, and a lower wiring structure 410.

According to an embodiment, the substrate 110 may include a first region 111 and a second region 112.

According to an embodiment, the first region 111 and the second region 112 may be any region among cell regions of the semiconductor device. For example, the first region 111 may correspond to a region where a protection diode is positioned to suppress electrical damage to transistors positioned in the second region 112. The protection diode may serve to bypass the charges generated during the plasma process to the first region 111.

According to another embodiment, the first region 111 may be any region among the dummy regions, and the second region 112 may be any region among the cell regions. In the present disclosure, the cell region may correspond to a region including electrically activated transistors, and the dummy region may correspond to a region including electrically inactivated transistors.

For example, the second region 112 may be any region among the cell regions, and the first region 111 may be positioned within a peripheral region positioned outside the cell region. Or, for example, if the substrate 110 includes a plurality of cell regions, and each of the plurality of cell regions includes a device region and a dummy region, the first region 111 may be positioned within the dummy region, and the second region 112 may be positioned within the device region.

The arrangement relationship of the first region 111 and the second region 112 illustrated in FIG. 2 is merely exemplary, and the arrangement of the first region 111 and the second region 112 may be changed in various ways.

According to an embodiment, the first region 111 may include an elemental semiconductor material such as silicon (Si) or germanium (Ge). Additionally, the first region 111 may include a compound semiconductor, for example, a group IV-IV compound semiconductor, a group II-VI compound semiconductor, or a group III-V compound semiconductor.

The IV-IV group compound semiconductor may be, for example, a binary compound or ternary compound including at least two or more of carbon (C), silicon (Si), germanium (Ge), and tin (Sn).

The III-V group compound semiconductor may be, for example, a binary compound, a ternary compound, or a quaternary compound formed by combining at least one of aluminum (Al), gallium (Ga), and indium (In), which are group III elements, with one of phosphorus (P), arsenic (As), and antimony (Sb), which are group V elements.

According to an embodiment, the first region 111 may include conductive impurities. For example, the first region 111 may include n-type impurities (or n-type dopant). The n-type impurities may include arsenic (As), phosphorus (P), antimony (Sb), or a combination thereof. Or, for example, the first region 111 may include p-type impurities (or p-type dopant). P-type impurities may include boron (B), aluminum (Al), gallium (Ga), indium (In), or combinations thereof.

According to an embodiment, the second region 112 may be an insulating substrate including an insulating material. For example, the second region 112 may include an oxide, a nitride, a nitrous oxide, or a combination thereof. For example, the second region 112 may include silicon nitride (SiNx). The second region 112 is depicted as a single film, but this is only for convenience of explanation and is not limited thereto.

According to an embodiment, the first side and the second side of the substrate 110 may be formed as planes parallel to the first direction D1 and the second direction D2 intersecting the first direction D1. For example, the first surface of the substrate 110 may be the upper surface, and the second surface may be the lower surface. The upper surface of the substrate 110 is a surface opposite the lower surface of the substrate 110 in the third direction D3. The third direction D3 is a direction perpendicular to the first direction D1 and the second direction D2, and may be the thickness direction of the substrate 110. The lower surface of the substrate 110 may be referred to as the back side of the substrate 110. In some embodiments, the logic circuitry of the cell region may be embodied on the upper surface of the substrate 110. In some embodiments, the lower wiring structure 410, described below, may be positioned on the lower surface of the substrate 110.

Referring to FIGS. 3 and 4, the substrate 110 has a trench defining a lower pattern BP and/or a protruding region 112a to be described later, and a field insulating film 105 may be positioned within the trench.

According to an embodiment, the field insulating film 105 may be positioned over the substrate 110. A field insulating film 105 may be placed to fill the inside of the trench.

Referring to FIG. 3, the field insulating film 105 may be positioned on the sidewall of the lower pattern BP on the first region 111. The field insulating film 105 may not be positioned on the upper surface of the lower pattern BP. The field insulating film 105 may cover the side of the lower pattern BP. According to an embodiment, a portion of the lower pattern BP may protrude in a third direction D3 from the upper surface of the field insulating film 105. At this time, the field insulating film 105 may cover all or part of the side wall of the lower pattern BP.

Referring to FIG. 4, the field insulating film 105 may be positioned on the side wall of the protruding region 112a on the second region 112. The field insulating film 105 may not be positioned on the upper surface of the protruding region 112a. The field insulating film 105 may cover the side of the protruding region 112a. According to an embodiment, a portion of the protruding region 112a may protrude in a third direction D3 from the upper surface of the field insulating film 105. At this time, the field insulating film 105 may cover all or part of the side wall of the protruding region 112a.

According to an embodiment, the field insulating film 105 may include an insulating material, such as an oxide, a nitride, a nitride, or a combination thereof. The field insulating film 105 is illustrated as a single film, but this is only for convenience of explanation and is not limited thereto.

According to an embodiment, the semiconductor device may include a channel patterns CP spaced apart along a first direction D1 on a first surface of a substrate 110, a first source/drain pattern SD1 positioned on a first region 111, second source/drain patterns SD2 connected to both sides of the channel pattern CP on a second region 112, and a gate structure GS surrounding the channel pattern CP and extending in the second direction D2.

According to an embodiment, a lower pattern BP may be positioned on a first region 111 of a substrate 110. The lower pattern BP may be portions protruding from the first surface of the first region 111 in the third direction D3. According to an embodiment, the lower patterns BP may be arranged spaced apart in the second direction D2 on the first surface of the first region 111.

According to an embodiment, a protruding region 112a may be positioned on the second region 112 of the substrate 110. The protruding region 112a may be portions that protrude in the third direction D3 from the first surface of the second region 112. According to an embodiment, the protruding region 112a may extend in the first direction D1 on the second region 112. The protruding regions 112a may be arranged spaced apart from each other in the second direction D2 on the first surface of the second region 112.

According to an embodiment, the channel patterns CP may be arranged spaced apart in a first direction D1 on the substrate 110. According to an embodiment, a plurality of channel patterns CP may be arranged spaced apart from each other in a third direction D3.

For example, each of the plurality of channel patterns CP may have a sheet shape. Each of the plurality of channel patterns CP may be a nanosheet having a thickness of several nanometers along the third direction D3.

According to an embodiment, the channel pattern CP may provide a passage for current to flow between the second source/drain patterns SD2 described below. For example, a channel pattern CP may be arranged between second source/drain patterns SD2 to connect the second source/drain patterns SD2.

According to an embodiment, the channel pattern CP may penetrate a portion of the gate structure GS in a direction (e.g., a first direction D1) intersecting with the direction in which the gate structure GS described below extends. In FIGS. 2 and 4, three channel patterns CP are depicted as being arranged spaced apart in the third direction D3, but this is not limited thereto, and the number of stacked channel patterns CP may be varied.

According to an embodiment, the channel patterns CP may include a semiconductor material. For example, channel patterns CP may include group IV semiconductors such as Si, Ge, group III-V compound semiconductors, group II-VI compound semiconductors, etc.

According to an embodiment, a lower pattern BP may be positioned below the first source/drain pattern SD1 to be described later on the first region 111.

According to an embodiment, a protruding region 112a may be positioned below the channel patterns CP on the second region 112. Specifically, the protruding region 112a may be positioned between the sub-gate structure S_GS positioned at the lowermost position among the plurality of sub-gate structures S_GS described below and the second region 112. The upper surface of the protruding region 112a may be in contact with the lower surface of the sub-gate structure S_GS positioned at the lowest position among the plurality of sub-gate structures S_GS.

According to an embodiment, the gate structure GS may be positioned on the substrate 110. According to an embodiment, the gate structure GS may extend in a second direction D2 on the substrate 110. The gate structures GS may be arranged spaced apart from each other in the first direction D1. The gate structure GS may include a plurality of sub-gate structures S_GS and a main gate structure M_GS. The sub-gate structure S_GS may be positioned on the substrate 110, and the main gate structure M_GS may be positioned on the sub-gate structure S_GS.

Each of the sub-gate structures S_GS may be composed of multiple layers. For example, each of the sub-gate structures S_GS may include a sub-gate electrode 120S and a sub-gate insulating film 130S. According to an embodiment, sub-gate structures S_GS and channel patterns CP may be alternately stacked in a third direction D3 over the second region 112.

In FIGS. 2 and 4, three sub-gate structures S_GS are depicted as being arranged spaced apart in the third direction D3, but the number of sub-gate structures S_GS arranged spaced apart is not limited thereto. For example, a gate structure GS may include four sub-gate structures S_GS.

According to an embodiment, the sub-gate electrode 120S may be formed on the protruding region 112a of the second region 112. The sub-gate electrode 120S may intersect with the protruding region 112a of the substrate 110. The sub-gate electrode 120S may surround the channel patterns CP.

The sub-gate electrode 120S may include at least one of a metal, a metal alloy, a conductive metal nitride, a metal silicide, a doped semiconductor material, a conductive metal oxide, and a conductive metal oxynitride. The sub-gate electrode 120S may be, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbide nitride (TiAlC—N), titanium aluminum carbide (TiAlC), titanium carbide (TiC), tantalum carbide nitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), It may include at least one of, but is not limited to, molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof. The conductive metal oxides and conductive metal nitrides may include, but are not limited to, oxidized forms of the materials described above.

The sub-gate insulating film 130S may extend along the upper surface of the protruding region 112a of the substrate 110. The sub-gate insulating film 130S may be positioned along the periphery of a plurality of sub-gate electrodes 120S. The sub-gate insulating film 130S may be in contact with the protruding region 112a of the substrate 110 and a plurality of channel patterns CP. A sub-gate insulating film 130S may be interposed between a plurality of channel patterns CP and a plurality of sub-gate electrodes 120S. The sub-gate insulating film 130S may include various insulating materials. Although not shown in FIGS. 2 to 4, the semiconductor device according to the embodiment may further include an internal gate spacer positioned between the sub-gate insulating film 130S and the first and second source/drain patterns SD1 and SD2 described below.

According to an embodiment, the sub-gate insulating film 130S is illustrated as a single film, but is not limited thereto. For example, the sub-gate insulating film 130S may be formed of a multi-film including silicon oxide (SiO₂) and a high-k material. At this time, the high-k material may include a material having a higher dielectric constant than silicon oxide (SiO₂), such as hafnium oxide (HfO), aluminum oxide (AlO), or tantalum oxide (TaO).

According to an embodiment, a main gate structure M_GS may be positioned on a sub-gate structure S_GS and a plurality of channel patterns CP. The main gate structure M_GS may be positioned on the upper surface of a channel pattern CP positioned at the uppermost position among a plurality of channel patterns CP.

Referring to FIG. 4, at least a portion of the gate electrode 120 may be positioned on a structure in which sub-gate electrodes 120S and channel patterns CP are alternately stacked. Another portion of the gate electrode 120 may cover both sides of the structure in which the sub-gate electrodes 120S and channel patterns CP are alternately stacked. At this time, four sides of the plurality of channel patterns CP may be surrounded by gate electrodes 120.

According to an embodiment, the main gate structure M_GS may include a main gate electrode 120M and a main gate insulating film 130M.

According to an embodiment, the main gate electrode 120M may be positioned over a sub-gate structure S_GS and a plurality of channel patterns CP. The main gate electrode 120M may include the same material as the sub-gate electrode 120S. For example, the main gate electrode 120M may include at least one of a metal, a metal alloy, a conductive metal nitride, a metal silicide, a doped semiconductor material, a conductive metal oxide, and a conductive metal oxynitride.

According to an embodiment, the main gate insulating film 130M may extend along the side and bottom surfaces of the main gate electrode 120M. The main gate insulating film 130M may extend along the side of the gate spacer 140 described later. The main gate insulating film 130M may include the same material as the sub gate insulating film 130S. For example, the main gate insulating film 130M may include various insulating materials.

According to an embodiment, the main gate insulating film 130M is illustrated as a single film, but is not limited thereto. For example, the main gate insulating film 130M may be formed of a multi-film including silicon oxide (SiO₂) and a high-k material. At this time, the high-k material may include a material having a higher dielectric constant than silicon oxide (SiO₂), such as hafnium oxide (HfO), aluminum oxide (AlO), or tantalum oxide (TaO).

A semiconductor device according to an embodiment may further include a gate spacer 140 and a capping layer 145.

According to an embodiment, the gate spacer 140 may be positioned on both sides of the main gate electrode 120M. The gate spacer 140 may not be placed between the substrate 110 and the channel pattern CP. According to an embodiment, the gate spacer 140 may not be placed between a plurality of channel patterns CP adjacent in the third direction D3.

The gate spacer 140 may include, for example, at least one of silicon nitride (SiN), silicon oxynitride (SiON), silicon oxide (SiO₂), silicon carbonitride (SiOCN), silicon boron nitride (SiBN), silicon oxyboron nitride (SiOBN), silicon oxycarbide (SiOC), and combinations thereof. Additionally, the gate spacer 140 is illustrated as being a single film, but this is only for convenience of explanation and is not limited thereto.

According to an embodiment, the capping layer 145 may be positioned over the main gate structure M_GS and the gate spacer 140. The upper surface of the capping layer 145 may be placed on the same plane as the upper surface of the first interlayer insulating layer 160. Although not shown, the capping layer 145 may be positioned between the gate spacers 140.

The capping layer 145 may include, for example, at least one of silicon nitride (SiN), silicon oxynitride (SiON), silicon carbon nitride (SiCN), silicon carbonate nitride (SiOCN), and combinations thereof. The capping layer 145 may include a material having an etching selectivity with respect to the first interlayer insulating layer 160.

Referring to FIGS. 2 and 3, the first and second source/drain patterns SD1 and SD2 may be positioned on the substrate 110. According to an embodiment, the first source/drain pattern SD1 may be positioned on a first region 111 of the substrate 110. The second source/drain pattern SD2 may be positioned on the second region 112 of the substrate 110.

Referring to FIGS. 1 and 3, the first source/drain patterns SD1 may be arranged spaced apart in the second direction D2 on the first region 111.

According to an embodiment, at least some of the first source/drain patterns SD1 may be connected to each other via a first contact pattern CA1 to be described later.

According to an embodiment, a plurality of lower patterns BP may be arranged spaced apart from each other along the second direction D2 on the first region 111, and the first source/drain pattern SD1 may be positioned on each of the lower patterns BP. Accordingly, the first source/drain patterns SD1 may be arranged to be spaced apart from each other along the second direction D2 by a distance substantially equal to the distance at which the plurality of lower patterns BP are spaced apart from each other.

Referring to FIGS. 1 and 2, the second source/drain pattern SD2 may be arranged spaced apart from each other along the first direction D1 on the protruding region 112a on the second region 112. A channel pattern CP and a gate structure GS may be positioned between the second source/drain patterns SD2. In other words, a plurality of second source/drain patterns SD2 and a plurality of channel patterns CP may be alternately arranged along a first direction D1 in which a protruding region 112a of the substrate 110 extends.

According to an embodiment, the second source/drain pattern SD2 may also be arranged in the second direction D2 on the second region 112. According to an embodiment, a plurality of protruding regions 112a may be arranged spaced apart from each other along a second direction D2 on a second region 112, and the second source/drain pattern SD2 may be positioned on each of the protruding regions 112a. Accordingly, the second source/drain patterns SD2 may be arranged to be spaced apart from each other along the second direction D2 by a distance substantially equal to the distance at which the plurality of protruding regions 112a are spaced apart from each other.

According to an embodiment, in the second region 112, the second source/drain pattern SD2 may be positioned on both sides of the channel patterns CP and/or the sub-gate structure S_GS. Specifically, two second source/drain patterns SD2 positioned on the protruding region 112a may be arranged spaced apart in a direction (e.g., the first direction D1) intersecting the direction in which the gate structure GS extends, with channel patterns CP or sub-gate structures S_GS therebetween.

The upper surfaces of the first and second source/drain patterns SD1 and SD2 may be positioned at substantially the same level as the upper surface of the channel pattern CP positioned at the uppermost position among the channel patterns CP, but are not limited thereto. The first and second source/drain patterns SD1 and SD2 may be in contact with the channel pattern CP and the sub-gate structure S_GS. However, this is not limited to the first source/drain pattern SD1 and may not be in contact with the channel pattern CP and the sub-gate structure S_GS. For example, although not shown, the first source/drain pattern SD1 may be in contact with a separating structure SDB to be described later.

According to an embodiment, the side surfaces of the first and second source/drain patterns SD1 and SD2 may have a bumpy embossing shape. In other words, the side surfaces of the first and second source/drain patterns SD1 and SD2 may have a wavy profile. For example, the side surfaces of the first and second source/drain patterns SD1 and SD2 adjacent to the sub-gate structure S_GS may have a roughly convex shape toward the sub-gate structure S_GS, and the side surfaces of the first and second source/drain patterns SD1 and SD2 adjacent to the channel patterns CP may have a roughly concave shape toward the channel patterns CP.

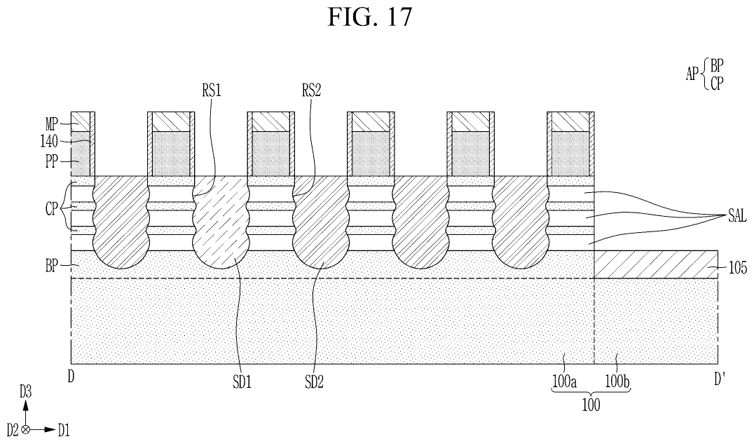

According to an embodiment, the first and second source/drain patterns SD1 and SD2 may be epitaxial patterns formed by a selective epitaxial growth process using an active pattern AP as a seed, which will be described later with reference to FIG. 17. According to an embodiment, the first and second source/drain patterns SD1 and SD2 may include the same semiconductor element (e.g., Si) as the semiconductor substrate 100 described below with reference to FIG. 17. The first source/drain pattern SD1 may serve to bypass charges generated during a semiconductor process to the first region 111. The second source/drain pattern SD2 may serve as a source/drain of a transistor that uses channel patterns CP as a channel region.

Although not shown, the first and second source/drain patterns SD1 and SD2 may include a first source/drain layer and a second source/drain layer. The first source/drain layer may have a form that surrounds the side and lower surfaces of the second source/drain layer. The channel patterns CP may be in contact with the first source/drain layer and may not be in contact with the second source/drain layer. Therefore, a first source/drain layer may be positioned between the channel patterns CP and the second source/drain layer. According to an embodiment, the lower surface of the first source/drain layer may be positioned at a similar or same level as the lower surface of the lowermost sub-gate structure S_GS among the sub-gate structures S_GS. However, it is not limited thereto, and the first and second source/drain patterns SD1 and SD2 may be formed as a single layer without being divided into a first source/drain layer and a second source/drain layer.

According to an embodiment, the first source/drain pattern SD1 and the second source/drain pattern SD2 may include impurities of different conductivity types. For example, the first source/drain pattern SD1 may include a first conductivity type impurity, and the second source/drain pattern SD2 may include a second conductivity type impurity that is different from the first conductivity type impurity.

According to an embodiment, the first source/drain pattern SD1 may include n-type impurities (or an n-type dopant). For example, the first source/drain pattern SD1 may include P, Sb, As, or a combination thereof. In this case, the second source/drain pattern SD2 may include p-type impurities (or a p-type dopant). For example, the second source/drain pattern SD2 may include B, V, In, Ga, Al, or a combination thereof.

According to another embodiment, the first source/drain pattern SD1 may include p-type impurities (or a p-type dopant). For example, the first source/drain pattern SD1 may include B, V, In, Ga, Al, or a combination thereof. In this case, the second source/drain pattern SD2 may include n-type impurities (or an n-type dopant). For example, the second source/drain pattern SD2 may include P, Sb, As, or a combination thereof.

Referring to FIG. 3, according to an embodiment, the first source/drain pattern SD1 may have a different bottom level from the field insulating film 105. According to an embodiment, the bottom level of the first source/drain pattern SD1 may be higher than the bottom level of the field insulating film 105. In other words, the lower surface of the first source/drain pattern SD1 may be positioned further from the bottom surface of the substrate 110 than the lower surface of the field insulating film 105. Although not shown, the second source/drain pattern SD2 may likewise have a lower surface level higher than the field insulating film 105.

Referring to FIG. 2, the lower surfaces of the first and second source/drain patterns SD1 and SD2 may be positioned at a level similar to or the same as the lower surface of the sub-gate structure S_GS positioned at the lowest among the sub-gate structures S_GS.

Although not shown, the bottom surface of the second source/drain pattern SD2 may be flat. At this time, the bottom surface of the first source/drain pattern SD1 may not be flat.

According to an embodiment, the semiconductor device may include a separating structure SDB that physically separates adjacent cells. According to an embodiment, the channel patterns of a cell may be terminated by a separating structure SDB. A separating structure SDB may be inserted to reduce the influence between adjacent cells, such as the Local Layout Effect (LLE), and to seperate regions doped with impurities between adjacent cells. According to an embodiment, the separating structure SDB may be composed of an insulating material.

Referring to FIG. 2, a pair of separation structures SDB may be provided on both sides of the first source/drain pattern SD1. For example, a pair of separating structures SDB may be provided on the boundary of the first region 111. According to an embodiment, the separating structure SDB may electrically separate the first source/drain pattern SD1 and the second source/drain pattern SD2 adjacent to each other in the first direction D1.

According to an embodiment, the separating structure SDB may penetrate the capping layer 145 and the gate structure GS positioned at both edges on the first region 111 in the third direction D3. The width (length along the first direction D1) of the separating structure SDB may be smaller than or substantially equal to the width of the gate structure GS. For example, when the width (length along the first direction D1) of the separating structure SDB is smaller than the width of the gate structure GS, unremoved gate structures GS may be positioned around the separating structure SDB. For example, the same material as the gate structures GS may be positioned to contact the outside of the separating structure SDB. For example, when the width (length along the first direction D1) of the separating structure SDB is substantially the same as the width of the gate structure GS, the separating structure SDB may be in contact with the first interlayer insulating layer 160 to be described later. According to an embodiment, the upper surface of the separating structure SDB may be positioned at substantially the same level as the upper surface of the capping layer 145.

For example, the separating structure SDB may include at least one of silicon oxide (SiO₂), silicon nitride (SiN), silicon oxynitride (SiON), and a low-k material.

A semiconductor device according to an embodiment may further include a first interlayer insulating layer 160 and a second interlayer insulating layer 170. The first interlayer insulating layer 160 may be positioned on the side surface of the gate spacer 140, the side surface of the capping layer 145, and the upper surface of the first and second source/drain patterns SD1 and SD2. The upper surface of the first interlayer insulating layer 160 may be positioned at substantially the same level as the upper surface of the separating structure SDB.

According to an embodiment, a second interlayer insulating layer 170 covering a capping layer 145 may be positioned on the first interlayer insulating layer 160 and the separating structure SDB. The boundary between the second interlayer insulating layer 170 and the first interlayer insulating layer 160 and/or the separating structure SDB may not be visible.

The first interlayer insulating layer 160 may include, for example, at least one of silicon oxide (SiO₂), silicon nitride (SiN), silicon oxynitride (SiON), and a low-k material. Low-k materials include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), and TriMethylSiloxane (HMDS). Borate (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped Silicon Oxide), OSG (Organo Silicate Glass), SiLK, Amorphous Fluorinated Carbon, silica aerogels, silica xerogels, may include, but is not limited to, mesoporous silica or combinations thereof.

The second interlayer insulating layer 170 may include the same material as the first interlayer insulating layer 160. For example, the second interlayer insulating layer 170 may include at least one of silicon oxide (SiO₂), silicon nitride (SiN), silicon oxynitride (SiON), and a low-k material.

A semiconductor device according to an embodiment may further include a first contact pattern CA1 connected to the first source/drain pattern SD1, a first contact via CAV1 connected to the first contact pattern CA1, a second contact pattern CA2 connected to at least one of the second source/drain patterns SD2, a second contact via CAV2 connected to the second contact pattern CA2, a gate contact pattern CB connected to at least one of the main gate electrodes 120M, and an upper wiring structure 210 positioned on a second interlayer insulating layer 170.

According to an embodiment, the first contact pattern CA1 may be electrically connected to the first source/drain pattern SD1 by penetrating the first interlayer insulating layer 160. According to an embodiment, the first contact via CAV1 may penetrate the second interlayer insulating layer 170 and be connected to the first contact pattern CA1. The first contact pattern CA1 may be connected to the upper wiring structure 210 described later through the first contact via CAV1. At this time, the first contact pattern CA1 and the first contact via CAV1 may serve to bypass the charges generated by plasma during the semiconductor process to the first region 111.

According to an embodiment, the second contact pattern CA2 may penetrate the first interlayer insulating layer 160 and be electrically connected to at least one of the second source/drain patterns SD2. According to an embodiment, the second contact via CAV2 may penetrate the second interlayer insulating layer 170 and be connected to the second contact pattern CA2. The second contact pattern CA2 may be connected to the upper wiring structure 210 described later through the second contact via CAV2. At this time, the second contact pattern CA2 and the second contact via CAV2 may serve to provide electrical signals or power supply voltage supplied from the outside to the second source/drain pattern SD2.

According to an embodiment, the first contact pattern CA1 may be positioned adjacent to the separating structure SDB in the first direction D1. According to an embodiment, the second contact pattern CA2 may be positioned adjacent to the main gate electrode 120M in the first direction D1.

For example, the first and second contact patterns CA1 and CA2 may include at least one of a metal, a metal alloy, a conductive metal nitride, a conductive metal carbide, a conductive metal oxide, a conductive metal carbonitride, and a two-dimensional (2D) material. The metal may include at least one of titanium (Ti), tantalum (Ta), tungsten (W), nickel (Ni), cobalt (Co), and platinum (Pt). The conductive metal nitride may include at least one of titanium nitride (TiN), tantalum nitride (TaN), tungsten nitride (WN), nickel nitride (NiN), cobalt nitride (CoN), and platinum nitride (PtN).

For example, the first and second contact via CAV1, and CAV2 may include aluminum, copper, tungsten, molybdenum, cobalt, or combinations thereof.

According to an embodiment, the gate contact pattern CB may be positioned on at least one of the main gate structures M_GS on the second region 112 of the substrate 110.

According to an embodiment, the gate contact pattern CB may penetrate the capping layer 145 and the second interlayer insulating layer 170 and be connected to at least one of the main gate electrodes 120M.

According to an embodiment, the gate contact pattern CB may electrically connect at least one of the upper wiring structure 210 and the main gate electrodes 120M. For example, the gate contact pattern CB may include aluminum, copper, tungsten, molybdenum, cobalt, or a combination thereof.

According to an embodiment, the upper wiring structure 210 may be positioned over the second interlayer insulating layer 170. The upper wiring structure 210 may include upper wirings 211, upper vias, and an upper insulating layer 212. The upper wiring 211 and upper vias may comprise metal (e.g., copper). An upper insulating layer 212 may be placed between the upper wirings 211 and the upper vias to insulate them. The upper insulating layer 212 may cover the second interlayer insulating layer 170. The upper wiring 211 and upper vias may be positioned within the upper insulating layer 212.

For example, the upper insulating layer 212 may include at least one of silicon oxide (SiOx), silicon nitride (SiNx), silicon oxynitride (SiON), or low-k dielectric films. The upper wiring structure 210 may be electrically connected to the main gate electrode 120M and at least one of the first and second source/drain patterns SD1 and SD2.

According to an embodiment, an electrical signal or power voltage supplied from the outside may be provided to the second source/drain patterns SD2 through the upper wiring structure 210 and the second contact pattern CA2 connected thereto.

A semiconductor device according to an embodiment may further include a lower contact pattern BCA positioned below at least one of the second source/drain patterns SD2, a first lower insulating layer 400 positioned on a lower surface of a substrate 110, a lower wiring structure 410 positioned below the first lower insulating layer 400, and a through via TSV connecting the upper wiring structure 210 and the lower wiring structure 410.

According to an embodiment, a first lower insulating layer 400 may be positioned on the second side of the substrate 110. According to an embodiment, a lower through via TSV2 may be positioned within the first lower insulating layer 400. According to an embodiment, the lower through via TSV2 may be connected to the upper through via TSV1. The lower through via TSV2 may be vertically overlapped with the upper through via TSV1. The lower through via TSV2 may be electrically connected to the lower wiring structure 410 positioned below the first lower insulating layer 400.

In the present disclosure, a through via TSV may be understood as a concept including a lower through via TSV2 positioned within a first lower insulating layer 400 and an upper through via TSV1 extending in a third direction D3 above the lower through via TSV2 and connected to an upper wiring structure 210.

According to an embodiment, a through via TSV may connect the lower wiring structure 410 and the upper wiring structure 210. According to an embodiment, a through via TSV may be connected to the first contact pattern CA1. The through via TSV and the first contact pattern CA1 may serve to bypass charges generated by plasma during the manufacturing process of a semiconductor device to the first region 111.

Through vias TSV may include conductive materials such as metal. For example, a through via TSV may include at least one of tungsten (W), molybdenum (Mo), ruthenium (Ru), aluminum (Al), titanium (Ti), or tantalum (Ta).

According to an embodiment, the lower contact pattern BCA may penetrate the second region 112 of the substrate 110 and be electrically connected to at least one of the second source/drain patterns SD2.

According to an embodiment, the lower contact pattern BCA may be positioned adjacent to the sub-gate electrode 120S in the first direction D1. According to an embodiment, the lower contact pattern BCA may electrically connect at least one of the lower wiring structure 410 and the second source/drain patterns SD2.

For example, the lower contact pattern BCA may include at least one of a metal, a metal alloy, a conductive metal nitride, a conductive metal carbide, a conductive metal oxide, a conductive metal carbonitride, and a two-dimensional (2D) material. The metal may include at least one of titanium (Ti), tantalum (Ta), tungsten (W), nickel (Ni), cobalt (Co), and platinum (Pt). The conductive metal nitride may include at least one of titanium nitride (TiN), tantalum nitride (TaN), tungsten nitride (WN), nickel nitride (NiN), cobalt nitride (CoN), and platinum nitride (PtN).

According to an embodiment, the lower wiring structure 410 may be positioned on the lower surface of the first lower insulating layer 400. The lower wiring structure 410 may include lower wirings 411, lower vias, and a second lower insulating layer 412. The lower wiring 411 and lower vias may comprise metal (e.g., copper). A second lower insulating layer 412 may be placed between the lower wirings 411 and the lower vias to insulate them. The second lower insulating layer 412 may cover the first lower insulating layer 400. At this time, the first lower insulating layer 400 and the second lower insulating layer 412 may include the same or similar materials, and the boundary between the first lower insulating layer 400 and the second lower insulating layer 412 may not be visible. The lower wiring 411 and lower vias may be positioned within the second lower insulating layer 412.

For example, the second lower insulating layer 412 may include at least one of silicon oxide (SiOx), silicon nitride (SiNx), silicon oxynitride (SiON), or low-k dielectric films. The lower wiring structure 410 may be electrically connected to at least one of the first and second source/drain patterns SD1 and SD2.

According to an embodiment, an electrical signal or power voltage supplied from the outside may be provided to the second source/drain patterns SD2 through the lower wiring structure 410 and the lower contact pattern BCA connected thereto.

As described above, the semiconductor device according to the present disclosure may bypass charges generated by plasma during a semiconductor process to the first region 111 by having the first region 111 including a semiconductor element positioned under the first source/drain pattern SD1.

As described above, the semiconductor device according to the present disclosure may effectively protect the semiconductor device by bypassing charges generated by plasma to the first region 111. Accordingly, deterioration of the electrical characteristics of semiconductor devices caused by charges generated by plasma may be prevented.

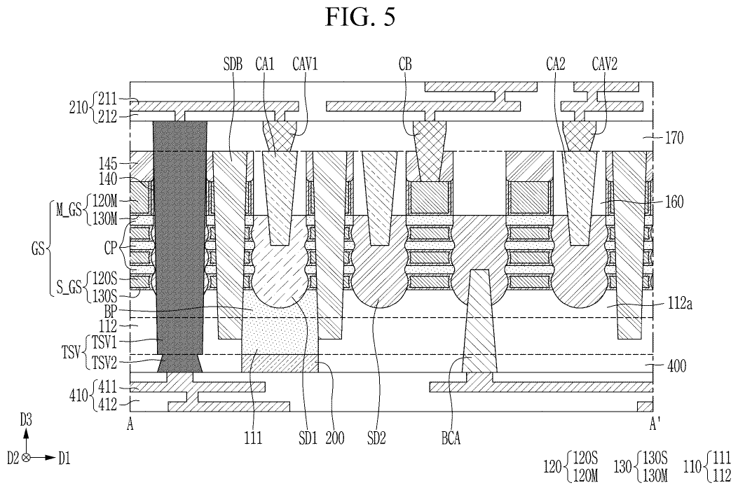

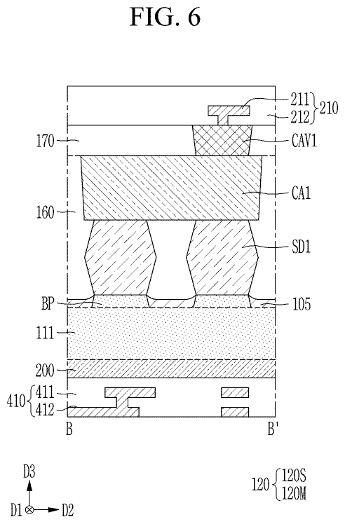

FIG. 5 is a cross-sectional view taken along line A-A′ of FIG. 1 according to another embodiment. FIG. 6 is a cross-sectional view taken along line B-B′ of FIG. 1 according to another embodiment.

The semiconductor devices illustrated in FIGS. 5 and 6 may include components similar to or identical to the semiconductor devices described with reference to FIGS. 1 to 4. However, the semiconductor element in this embodiment is different from that illustrated in FIGS. 1 to 4 in that the structure relates to a mask pattern 200 positioned under the first region 111 of the substrate 110. Here, any content that overlaps with that described above in FIGS. 1 to 4 will be briefly explained or omitted, and the differences will be mainly explained.

Referring to FIGS. 5 and 6, a semiconductor device according to an embodiment may further include a mask pattern 200 positioned below the first region 111. In the method for manufacturing a semiconductor device described below with reference to FIGS. 17 to 27, if the mask pattern 200 is not removed, the mask pattern 200 may remain under the first region 111.

According to an embodiment, the planar shape of the mask pattern 200 may be substantially identical to the planar shape of the first region 111. The planar area of the mask pattern 200 may be substantially equal to the planar area of the first region 111. In other words, the mask pattern 200 may cover the first region 111. For example, the mask pattern 200 may be in contact with the lower surface of the first region 111, but is not limited thereto.

According to an embodiment, the mask pattern 200 may be positioned between the first region 111 and the lower wiring structure 410. According to an embodiment, the upper level of the mask pattern 200 may be substantially identical to the upper level of the first lower insulating layer 400. According to an embodiment, the lower level of the mask pattern 200 may be substantially identical to the lower level of the first lower insulating layer 400.

For example, the mask pattern 200 may be formed of a hard mask including an oxide film, polysilicon, or a combination thereof.

As described above, the semiconductor device according to the present disclosure may suppress the occurrence of charge damage by discharging charges due to plasma to the first region 111 by leaving the first region 111 without being removed by the mask pattern 200.

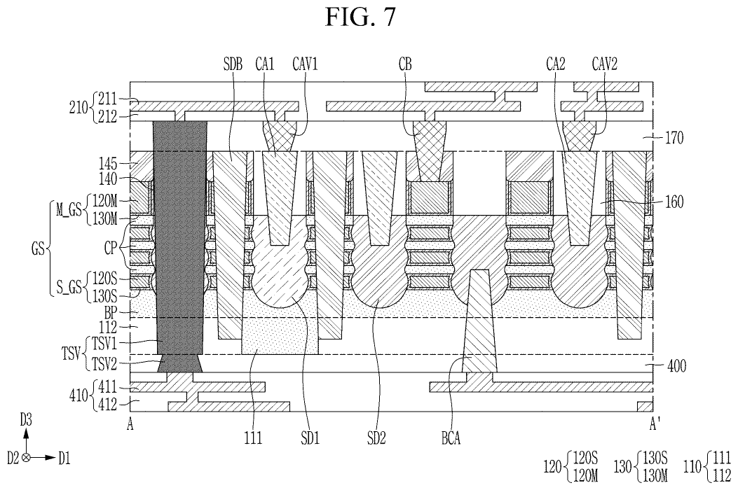

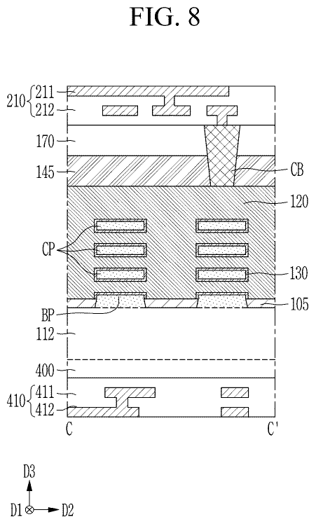

FIG. 7 is a cross-sectional view taken along line A-A′ of FIG. 1 according to another embodiment. FIG. 8 is a cross-sectional view taken along line C-C′ of FIG. 1 according to another embodiment.

The semiconductor devices illustrated in FIGS. 7 and 8 may include components similar to or identical to the semiconductor devices described with reference to FIGS. 1 to 4. However, the semiconductor element in this embodiment is different from that illustrated in FIGS. 1 to 4 in that the lower pattern BP is positioned on the first region 111 and the second region 112 of the substrate 110. Here, any content that overlaps with that described above in FIGS. 1 to 4 will be briefly explained or omitted, and the differences will be mainly explained.

Referring to FIGS. 7 and 8, a semiconductor device according to an embodiment may further include a lower pattern BP positioned on a substrate 110. Specifically, the lower pattern BP may be positioned entirely over the first region 111 and the second region 112. In the method for manufacturing a semiconductor device described later with reference to FIGS. 17 to 27, if the semiconductor substrate 100 described later is not completely removed, a lower pattern BP may remain on the substrate 110.

According to an embodiment, the lower pattern BP may have a predetermined thickness on the substrate 110. Although not shown in FIGS. 7 and 8, the thickness of the lower pattern BP positioned over the first region 111 may be different from the thickness of the lower pattern BP positioned over the second region 112. For example, the thickness of the lower pattern BP positioned on the first region 111 may be greater than the thickness of the lower pattern BP positioned on the second region 112.

According to an embodiment, the lower pattern BP may be extended in the first direction D1. According to an embodiment, the lower pattern BP may be portions protruding from the substrate 110 in the third direction D3.

The lower pattern BP may be formed by etching a portion of the semiconductor substrate 100 to be described later, or may include an epitaxial layer grown from the semiconductor substrate 100 to be described later. The lower pattern BP may include elemental semiconductor material such as silicon (Si) or germanium (Ge). Additionally, the lower pattern BP may include a compound semiconductor.

According to an embodiment, a plurality of channel patterns CP on the second region 112 may be positioned on an upper surface of a lower pattern BP. A plurality of channel patterns CP on the second region 112 may be separated from the lower pattern BP in the third direction D3.

According to an embodiment, a gate structure GS on the second region 112 may be positioned on a lower pattern BP. The gate structure GS on the second region 112 may intersect with the lower pattern BP.

According to an embodiment, the first and second source/drain patterns SD1 and SD2 on the first and second regions 111 and 112 may be positioned over the lower pattern BP.

According to an embodiment, even when the lower pattern BP is positioned on the first region 111 and the second region 112, as described above with reference to FIG. 4, a pair of separation structures SDB may be provided on both sides of the first source/drain pattern SD1. For example, a pair of disjoint structures SDB may be provided on the boundary of the first region 111. According to an embodiment, the separating structure SDB may electrically seperate the first source/drain pattern SD1 and the second source/drain pattern SD2, which are adjacent to each other in the first direction D1.

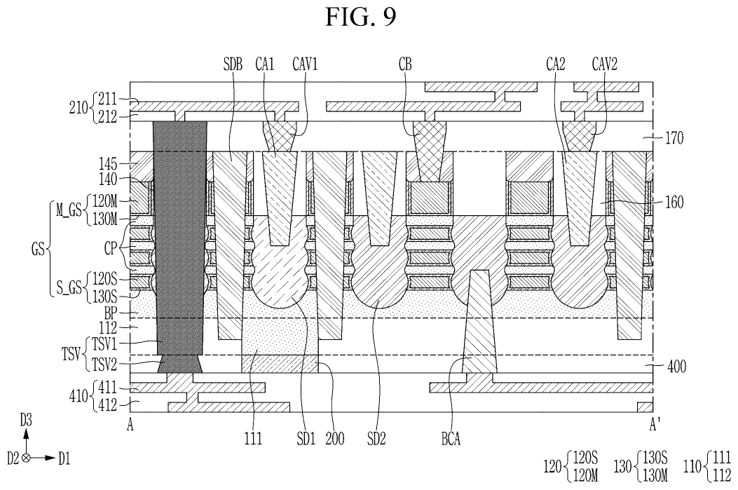

FIG. 9 is a cross-sectional view taken along line A-A′ of FIG. 1 according to another embodiment.

The semiconductor device illustrated in FIG. 9 may include components similar to or identical to the semiconductor device described in FIG. 1 referring to FIG. 4. However, the semiconductor device in the present embodiment has a structure in which, unlike those illustrated in FIG. 1 to FIG. 4, a lower pattern BP is positioned on the first region 111 and the second region 112 of the substrate 110, and a mask pattern 200 is positioned below the first region 111. Here, any overlapping content from FIG. 1 to FIG. 4 will be briefly explained or omitted, and the differences will be explained primarily.

Referring to FIG. 9, in a semiconductor device according to an embodiment, a lower pattern BP may be positioned on the first region 111 and the second region 112, and a mask pattern 200 may be positioned below the first region 111.

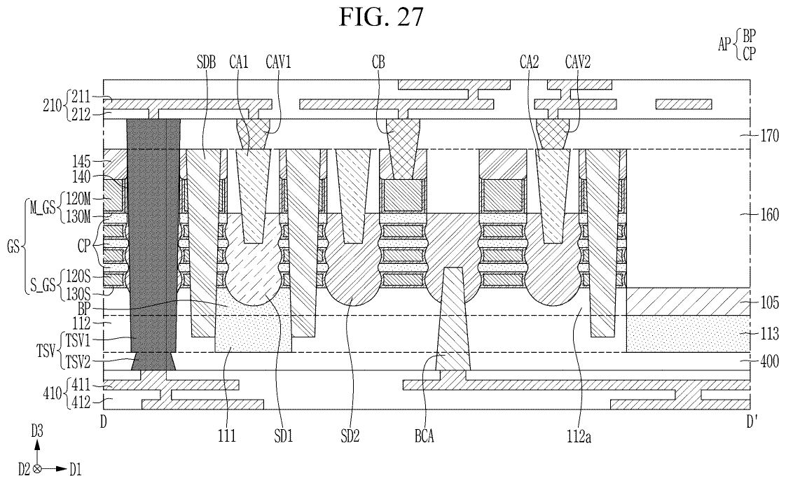

In FIG. 17 referring to FIG. 27, in a method of manufacturing a semiconductor device to be described later, if the semiconductor substrate 100 to be described later is not completely removed and the mask pattern 200 is not removed, a lower pattern BP may remain on the first region 111 and the second region 112, and the mask pattern 200 may remain under the first region 111.

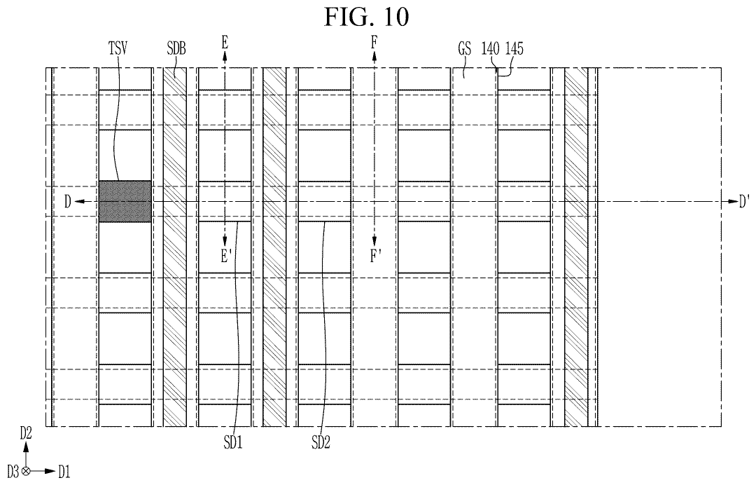

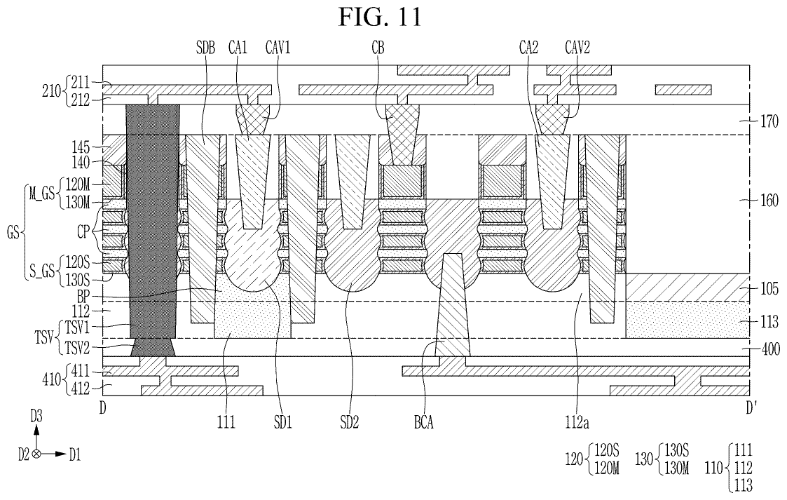

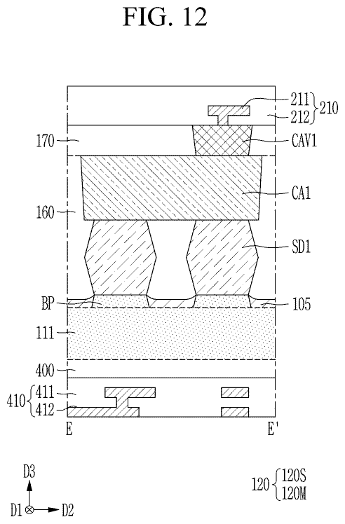

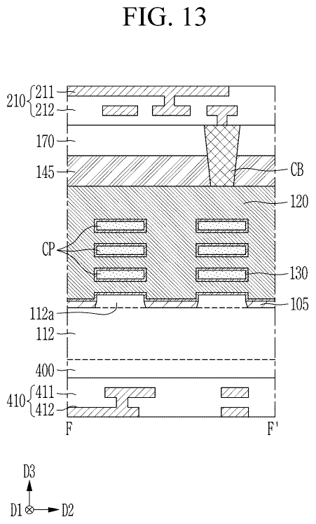

FIG. 10 is a top plan view showing a semiconductor device according to another embodiment. FIG. 11 is a cross-sectional view taken along line D-D′ of FIG. 10 according to an embodiment. FIG. 12 is a cross-sectional view taken along line E-E′ of FIG. 10 according to an embodiment. FIG. 13 is a cross-sectional view taken along line F-F′ of FIG. 10 according to an embodiment.

The semiconductor devices illustrated in FIG. 10 to FIG. 13 may include components similar to or identical to the semiconductor devices described in FIG. 1 to FIG. 4. However, the semiconductor device in the present embodiment has a structure that includes an additional passive component cell region (e.g., third region 113), which is different from what is illustrated in FIG. 1 to FIG. 4. Here, any overlapping content from FIG. 1 to FIG. 4 will be briefly explained or omitted, and the differences will be explained primarily.

Referring to FIGS. 10 to 13, a semiconductor device according to an embodiment may include a substrate 110 including a first region 111, a second region 112 and a third region 113. For example, the first region 111 and second region 112 may correspond to cell regions, and the third region 113 may correspond to a passive element cell region. Or, for example, the first region 111 may correspond to a dummy region, the second region 112 may correspond to a cell region, and the third region 113 may correspond to a passive cell region.

According to an embodiment, logic transistors forming a logic circuit may be positioned on the second region 112 of the substrate 110. A protection diode may be positioned on the first region 111 of the substrate 110 to suppress electrical damage to logic transistors on the second region 112. Passive components may be placed on the third region 113. For example, the third region 113 may include passive components such as a resistor, a capacitor, or an inductor.

The arrangement relationship of the first region 111, the second region 112, and the third region 113 illustrated in FIG. 11 is merely exemplary, and the arrangement of the first region 111, the second region 112, and the third region 113 may be changed in various ways.

According to an embodiment, the first region 111 and the third region 113 may include the same material, and the first region 111 and the second region 112 may include different materials. Similarly, second region 112 and third region 113 may include different materials.

According to an embodiment, the first region 111 may be a semiconductor substrate including silicon, germanium, silicon-germanium, or a compound semiconductor substrate. For example, the first region 111 may be a silicon substrate.

According to an embodiment, the first region 111 may include conductive impurities. For example, the first region 111 may include n-type impurities (or n-type dopant). N-type impurities may include arsenic (As), phosphorus (P), antimony (Sb) or a combination thereof. Or, for example, the first region 111 may include p-type impurities (or p-type dopant). P-type impurities may include boron (B), aluminum (Al), gallium (Ga), indium (In) or a combination thereof.

According to an embodiment, the second region 112 may be an insulation substrate including an insulating material. For example, second region 112 may include oxide, nitride, nitrous oxide or a combination thereof. For example, second region 112 may include silicon nitride (SiNx). Second region 112 is depicted as a single membrane, but this is only for better understanding and ease of description and is not limited thereto.

According to an embodiment, the third region 113 may be a semiconductor substrate including silicon, germanium, silicon-germanium, or a compound semiconductor substrate. For example, third region 113 may be a silicon substrate.

According to an embodiment, the first plane and the second plane of the substrate 110 may be formed as planes parallel to the first direction D1 and the second direction D2 intersecting the first direction D1. For example, the first surface of substrate 110 may be the top surface, and the second surface may be the bottom surface. The upper surface of substrate 110 is a surface opposite to the bottom surface of substrate 110 in the third direction D3. The third direction D3 may be a direction perpendicular to the first direction D1 and the second direction D2. The bottom surface of substrate 110 may be referred to as the back side of substrate 110.

Referring to FIGS. 12 and 13, a substrate 110 has a trench defining a lower pattern BP and/or protruding region 112a, within which a field insulation layer 105 may be positioned.

According to an embodiment, the field insulation layer 105 may be positioned over the substrate 110. Field insulation layer 105 may be placed to fill the inside of the trench. For example, the field insulation layer 105 may include silicon oxide.

Referring to FIG. 12, the field insulation layer 105 may be positioned on the sidewall of the lower pattern BP on the first region 111. Referring to FIG. 13, field insulation layer 105 may be positioned on the sidewall of protruding region 112a on second region 112. The field insulation layer 105 may extend in the first direction D1 to cover the upper surface of the third region 113.

According to an embodiment, a first interlayer insulating layer 160 may be provided on a substrate 110. The first interlayer insulating layer 160 may cover the first and second source/drain patterns SD1, and SD2. The upper surface of the first interlayer insulating layer 160 may be substantially coplanar with the upper surface of the capping layer 145. The first interlayer insulating layer 160 may extend in the first direction D1 to cover the upper surface of the field insulation layer 105 on the third region 113.

According to an embodiment, a second interlayer insulating layer 170 covering a capping layer 145 may be positioned on the first interlayer insulating layer 160. An upper insulation layer 212 may be positioned on the second interlayer insulating layer 170. The second interlayer insulating layer 170 and the upper insulation layer 212 may be extended in the first direction D1 and also provided on the third region 113.

For example, the first interlayer insulating layer 160, the second interlayer insulating layer 170, and the upper insulation layer 212 may include at least one of silicon oxide (SiOx), silicon nitride (SiNx), silicon nitride (SiON), or low dielectric layers.

According to an embodiment, separate structures SDB may be provided at the boundaries between cells, respectively. A separating structure SDB may be positioned between the first region 111 and the second region 112. A separating structure SDB may be positioned between the second region 112 and the third region 113. For example, each of the first region 111 and the second region 112 may be positioned between a pair of separating structures SDB.

According to an embodiment, the separating structure SDB may extend parallel to the gate electrodes 120 in the second direction D2. According to an embodiment, the separating structure SDB may penetrate the capping layer 145 and the gate structure GS positioned at both edges of the first region 111 and the second region 112, respectively, in the third direction D3. The width (length along the first direction D1) of the separating structure SDB may be smaller than or substantially the same as the width of the gate structure GS.

For example, the separating structure SDB may include at least one of silicon oxide (SiO₂), silicon nitride (SiN), silicon nitride (SiON), and a low dielectric constant material.

According to an embodiment, a first lower insulation layer 400 may be positioned on a second surface of a substrate 110, and a lower wire structure 410 may be positioned below the first lower insulation layer 400.

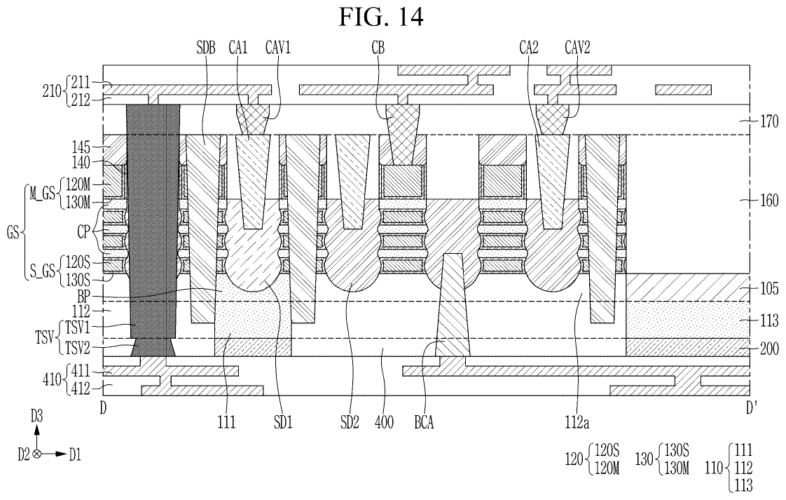

FIG. 14 is a cross-sectional view taken along line D-D′ of FIG. 10 according to another embodiment.

The semiconductor device illustrated in FIG. 14 may include components similar to or identical to the semiconductor device described in FIG. 10 referring to FIG. 13. However, the semiconductor device in the present embodiment is different from that illustrated in FIG. 10 to FIG. 13 in that the structure is such that the mask pattern 200 is positioned below the first region 111 and the third region 113. Here, any overlapping content from FIG. 10 to FIG. 13 will be briefly explained or omitted, and the differences will be explained primarily.

Referring to FIG. 14, in a semiconductor device according to an embodiment, a mask pattern 200 may be positioned under the first region 111 and the third region 113. In FIG. 17 referring to FIG. 27, in a method of manufacturing a semiconductor device to be described later, if the mask pattern 200 is not removed, the mask pattern 200 may remain under the first region 111 and the third region 113.

According to an embodiment, the planar area of the mask pattern 200 positioned below the first region 111 may be substantially the same as the planar area of the first region 111. According to an embodiment, the planar area of the mask pattern 200 positioned below the third region 113 may be substantially the same as the planar area of the third region 113. In other words, mask pattern 200 may cover first region 111 and third region 113. For example, mask pattern 200 may contact the bottom surface of first region 111 and third region 113, but is not limited thereto.

According to an embodiment, the mask pattern 200 may be positioned between the first region 111 and the lower wire structure 410. Additionally, mask pattern 200 may be positioned between third region 113 and lower wire structure 410.

According to an embodiment, the upper level of the mask pattern 200 may be substantially the same as the upper level of the first lower insulation layer 400. According to an embodiment, the lower level of the mask pattern 200 may be substantially the same as the lower level of the first lower insulation layer 400.

For example, mask pattern 200 may be formed of a hard mask including an oxide layer, polysilicon, or a combination thereof.

As described above, the semiconductor device according to the present disclosure may suppress the occurrence of charge damage by discharging the charge due to plasma to the first region 111 since the first region 111 is not removed by the mask pattern 200 and remains.

Additionally, as described above, the semiconductor device according to the present disclosure may increase process efficiency by simultaneously leaving the first region 111 while protecting the passive component region on the third region 113 with the mask pattern 200.

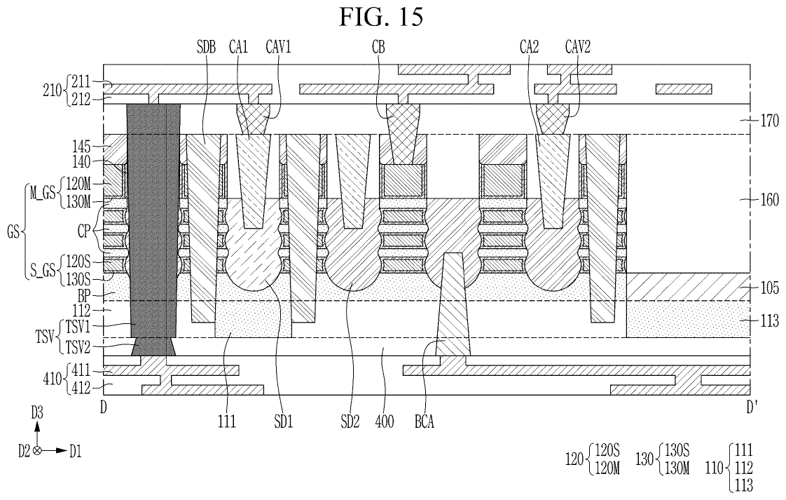

FIG. 15 is a cross-sectional view taken along line D-D′ of FIG. 10 according to another embodiment.

The semiconductor device illustrated in FIG. 15 may include components similar to or identical to the semiconductor device described in FIG. 10 referring to FIG. 13. However, the semiconductor device in the present embodiment is different from that illustrated in FIG. 10 to FIG. 13 in that the structure is such that the lower pattern BP is positioned on the first region 111 and the second region 112. Here, any overlapping content from FIG. 10 to FIG. 13 will be briefly explained or omitted, and the differences will be explained primarily.

Referring to FIG. 15, a semiconductor device according to an embodiment may further include a lower pattern BP positioned over the first region 111 and the second region 112. Specifically, the lower pattern BP may be positioned entirely over the first region 111 and the second region 112. In FIG. 17 referring to FIG. 27, in a method of manufacturing a semiconductor device to be described later, if the semiconductor substrate 100 to be described later is not completely removed, a lower pattern BP may remain on the first region 111 and the second region 112.

According to an embodiment, the lower pattern BP may have a predetermined thickness over the first region 111 and the second region 112. Although not shown in FIG. 15, the thickness of the lower pattern BP positioned on the first region 111 may be different from the thickness of the lower pattern BP positioned on the second region 112. For example, the thickness of the lower pattern BP positioned on the first region 111 may be greater than the thickness of the lower pattern BP positioned on the second region 112.

According to an embodiment, the lower pattern BP may be extended in the first direction D1 over the first region 111 and the second region 112. According to an embodiment, the lower pattern BP may be portions protruded from the first region 111 and the second region 112 in the third direction D3.

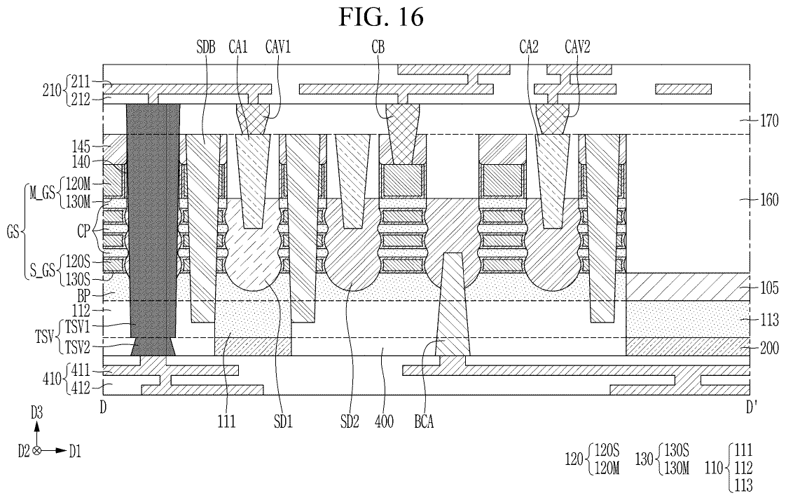

FIG. 16 is a cross-sectional view taken along line D-D′ of FIG. 10 according to another embodiment.

The semiconductor device illustrated in FIG. 16 may include components similar to or identical to the semiconductor device described in FIG. 10 referring to FIG. 13. However, the semiconductor device in the present embodiment has a structure in which the lower pattern BP is positioned above the first region 111 and the second region 112, and the mask pattern 200 is positioned below the first region 111 and the third region 113, unlike those illustrated in FIG. 10 to FIG. 13. Here, any overlapping content from FIG. 10 to FIG. 13 will be briefly explained or omitted, and the differences will be explained primarily.

Referring to FIG. 16, in a semiconductor device according to an embodiment, a lower pattern BP may be positioned on the first region 111 and the second region 112, and a mask pattern 200 may be positioned under the first region 111 and the third region 113.

In FIG. 17 to FIG. 27, in a method of manufacturing a semiconductor device to be described later, if the semiconductor substrate 100 to be described later is not completely removed and the mask pattern 200 is not removed, a lower pattern BP may remain on the first region 111 and the second region 112, and the mask pattern 200 may remain under the first region 111 and the third region 113.

FIGS. 17, 18, 19, 20, 21, 22, 23, 24, 25, 26, and FIG. 27 are cross-sectional views illustrating a method of manufacturing a semiconductor device according to an embodiment. FIG. 17 to FIG. 27 correspond to the cross-sectional views taken along the line D-D′ of FIG. 10.

Referring to FIG. 17, a semiconductor substrate 100 may be provided. The semiconductor substrate 100 may include a first portion 100a on which a logic transistor forming a logic circuit and a protection diode protecting the logic transistor are formed, and a second portion 100b on which a passive element is formed.

According to an embodiment, sacrificial layers SAL and active layers are formed alternately on a first portion 100a of a semiconductor substrate 100. The sacrificial layer SAL may include a material that may have etch selectivity with respect to the active layers. For example, the active layers may include silicon (Si), and the sacrificial layers SAL may include silicon-germanium (SiGe).

According to an embodiment, sacrificial layers SAL and active layers may not be formed on the second portion 100b.

According to an embodiment, mask patterns may be formed on a first portion 100a of a semiconductor substrate 100. The mask pattern may have a line shape or a bar shape that extends in the second direction D2. By performing a patterning process using mask patterns as an etching mask, a trench defining a lower pattern BP may be formed. Accordingly, a lower pattern BP may be formed on the first portion 100a. From the perspective of the flat area, the lower patterns BP may have a line shape that extends parallel to each other in the first direction D1. According to an embodiment, a stacked pattern may be positioned on top of a lower pattern BP. The stacked pattern may include active layers and sacrificial layers SAL alternately stacked.

Next, a field insulation layer 105 may be formed to fill the trench. Specifically, an insulation layer covering the lower pattern BP and the stacked patterns may be formed on the first surface of the semiconductor substrate 100. By recessing the insulation layer until the stacked patterns are exposed, a field insulation layer 105 may be formed. According to an embodiment, the field insulation layer 105 may extend in the first direction D1 to cover the upper surface of the second portion 100b on the second portion 100b of the semiconductor substrate 100.

The field insulation layer 105 may include an insulating material such as silicon oxide. The stacked patterns may be exposed above the field insulation layer 105. In other words, the stacked patterns may be protruded vertically over the field insulation layer 105.

Next, a sacrificial layer may be formed on the front surface of the first portion 100a, a hard mask pattern MP may be formed on the sacrificial layer, and the sacrificial layer may be patterned using the hard mask pattern MP as an etching mask to form a sacrificial pattern PP.

According to an embodiment, the sacrificial pattern PP may be formed in a line shape or a bar shape extending in the second direction D2. The sacrificial patterns PP may be arranged spaced apart along the first direction D1 at a predetermined pitch. For example, the sacrificial layer may include polysilicon.

Next, a pair of gate spacers 140 may be formed on both sidewalls of each sacrificial pattern PP.

According to an embodiment, a gate spacer film may be conformally formed on the entire surface of the first portion 100a, and the gate spacer film may be anisotropically etched to form a gate spacer 140.

According to an embodiment, the gate spacer film may include SiCN, SiCON, SiN, or a combination thereof. Additionally, the gate spacer film may be formed of a multi-layer including SiCN, SiCON, SiN, or a combination thereof.

According to an embodiment, by etching the upper portion of the active pattern AP using a hard mask pattern MP and gate spacer 140 as an etching mask, first recess RS1 and second recess R2 may be formed. Each of the first recess RS1 and the second recess R2 may be formed between a pair of sacrificial patterns PP.

Next, the first source/drain pattern SD1 and the second source/drain pattern SD2 are formed in the first recess RS1 and the second recess RS2, respectively. According to an embodiment, the first source/drain pattern SD1 and the second source/drain pattern SD2 may be formed by performing a selective epitaxial growth (SEG) process using the interior walls of the first recess RS1 and the second recess RS2 as seed layers. According to an embodiment, the SEG process may include a chemical vapor deposition (Chemical Vapor Deposition: CVD) process or a molecular beam epitaxy (Molecular Beam Epitaxy: MBE) process.

Alternatively, according to an embodiment, impurities of different conductivity types may be implanted in the first source/drain pattern SD1 and the second source/drain pattern SD2. In other words, a first conductivity type impurity may be implanted in the first source/drain pattern SD1, and a second conductivity type impurity may be implanted in the second source/drain pattern SD2.

For example, the first source/drain pattern SD1 may be doped to have n-type impurities, and the second source/drain pattern SD2 may be doped to have p-type impurities. Or, for example, the first source/drain pattern SD1 may be doped to have p-type impurities, and the second source/drain pattern SD2 may be doped to have n-type impurities.

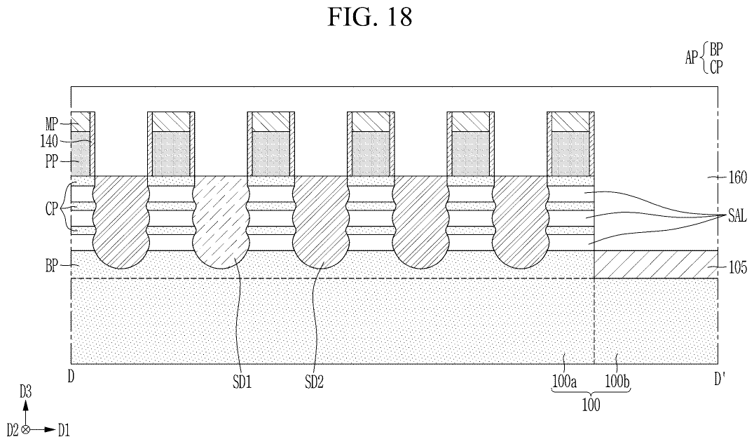

Referring to FIG. 18, a first interlayer insulating layer 160 covering the first and second source/drain patterns SD1 and SD2 may be formed.

First, a first interlayer insulating layer 160 is formed covering the first and second source/drain patterns SD1 and SD2, the hard mask pattern MP and the gate spacer 140 on the first portion 100a and the field insulation layer 105 on the second portion 110b. For example, the first interlayer insulating layer 160 may comprise silicon oxide.

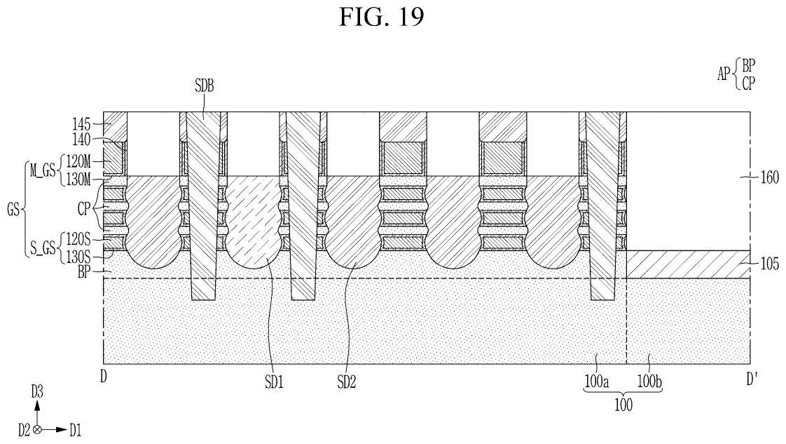

Referring to FIG. 19, after removing the sacrificial layers SAL, an embodiment, the gate electrode 120 may be formed.

According to an embodiment, the first interlayer insulating layer 160 may be planarized until the upper surface of the sacrificial pattern PP is exposed. Planarization of the first interlayer insulating layer 160 may be performed using an etch back (Etch Back) or CMP (chemical mechanical polishing) process. During the planarization process, the hard mask pattern MP may be completely removed. As a result, the upper surface of the first interlayer insulating layer 160 may be positioned at substantially the same level as the upper surface of the sacrificial pattern PP and the upper surface of the gate spacer 140.

Next, the exposed sacrificial pattern PP may be selectively removed. By removing the sacrificial pattern PP, first empty spaces may be formed to expose the active pattern AP. By removing the sacrificial pattern PP, sacrificial layers SAL may be exposed through the first empty space.

Next, sacrificial layers SAL exposed through the first empty space may be selectively removed. According to an embodiment, by performing an etching process that selectively etches sacrificial layers SAL, only sacrificial layers SAL may be removed while leaving channel patterns CP intact. The etching process may have a high etch rate for silicon-germanium having a relatively high germanium concentration.

For example, the etching process may be wet etching. The etching material used in the etching process may rapidly remove the sacrificial layer SAL with a relatively high germanium concentration.

By selectively removing the sacrificial layers SAL, only the channel patterns CP remain on the lower pattern BP. Second empty spaces may be formed through regions where sacrificial layers SAL have been removed. Second empty spaces may be positioned between channel patterns CP.

The sub-gate insulation layer 130S and the main gate insulation layer 130M are conformally formed within the first and second empty spaces. Afterwards, the gate electrode 120 may be formed on the sub-gate insulation layer 130S and the main gate insulation layer 130M. The gate electrode 120 may include a sub-gate electrode 120S formed on a sub-gate insulation layer 130S and a main gate electrode 120M formed on a main gate insulation layer 130M.

After that, the upper part of the main gate electrode 120M, the main gate insulation layer 130M around it, and the upper part of a plurality of gate spacers 140 may be removed. Afterwards, the removed upper space may be filled with an insulating material to form a capping layer 145.

Next, a separating structure SDB may be formed on both sides of the first source/drain pattern SD1. A trench may be formed to expose at least a portion of the lower pattern BP by penetrating the capping layer 145 and the gate structure GS positioned on both sides of the first source/drain pattern SD1, and a separating structure SDB may be formed to fill the trench. According to an embodiment, the semiconductor device may further include a separating structure SDB penetrating the second portion 100b and the capping layer 145 and the gate structure GS adjacent to each other in the first direction.

According to an embodiment, as a trench is formed from the upper surface of the capping layer 145 toward the lower pattern BP, the width of the separating structure SDB along the first direction D1 may decrease while extending from the upper side to the lower side in the third direction D3. However, it is not limited thereto, and although not shown, a trench may be formed from a substrate made of an insulating material toward the capping layer 145 after the lower pattern BP is replaced with an insulating material. Accordingly, the width of the separating structure SDB along the first direction D1 may increase as it extends from top to bottom along the third direction D3.

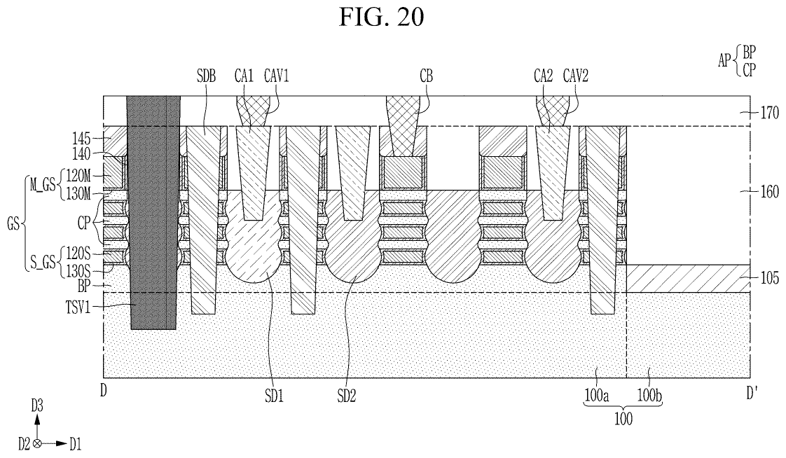

Referring to FIG. 20, a first contact pattern CA1 positioned on the first source/drain pattern SD1 and a second contact pattern CA2 positioned on the second source/drain pattern SD2 may be formed.

According to an embodiment, a first contact pattern CA1 and a second contact pattern CA2 are formed that are electrically connected to the first source/drain pattern SD1 and the second source/drain pattern SD2, respectively, by penetrating the first interlayer insulating layer 160.

According to an embodiment, a capping layer 145, a first interlayer insulating layer 160, and a second interlayer insulating layer 170 covering a separating structure SDB may be formed. For example, the second interlayer insulating layer 170 may include at least one of silicon oxide (SiO₂), silicon nitride (SiN), silicon nitride (SiON), and a low dielectric constant material.

Afterwards, the first and second contact patterns CA1 and CA2, respectively, may be formed via the first and second contacts CAV1 and CAV2, and the gate contact pattern CB connected to the main gate electrode 120M.

According to an embodiment, the second interlayer insulating layer 170 may have through holes opening in the third direction D3. According to an embodiment, first and second contact via CAV1, and CAV2 and gate contact pattern CB may be inserted into the through holes of the second interlayer insulating layer 170. In other words, the penetration holes of the second interlayer insulating layer 170 may be arranged at positions that overlap with the first and second contact via CAV1, and CAV2 and the gate contact pattern CB in the third direction D3.

According to an embodiment, the first and second contacts via CAV1 and CAV2 may be connected to the first and second contact patterns CA1 and CA2, respectively, by penetrating the second interlayer insulating layer 170. According to an embodiment, the gate contact pattern CB may be connected to the main gate electrode 120M through the second interlayer insulating layer 170 and the capping layer 145.

According to an embodiment, through-holes may be formed to penetrate the first and second interlayer insulating layers 160 and 170 to expose the semiconductor substrate 100. An upper through via TSV1 may be formed inside the through-hole. Forming the upper penetration via TSV1 may involve at least one deposition process among PVD, CVD and ALD. For example, the upper through via TSV1 may include at least one of tungsten (W), molybdenum (Mo), ruthenium (Ru), aluminum (Al), titanium (Ti), and tantalum (Ta).

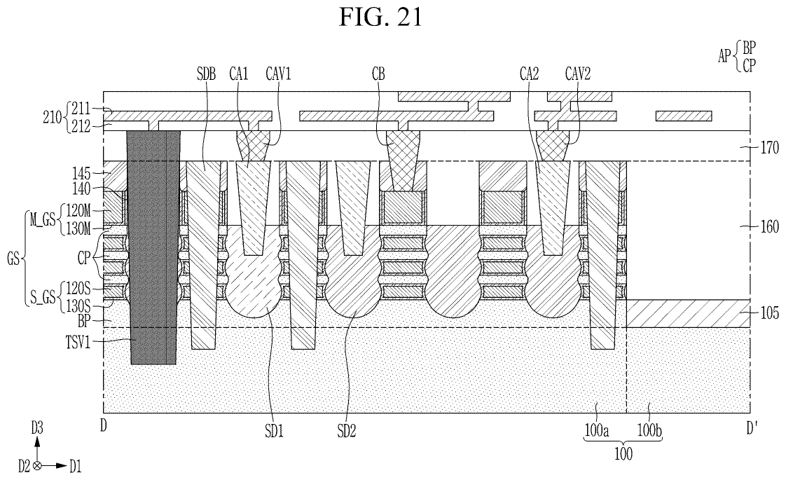

Referring to FIG. 21, first and second contacts via CAV1, and CAV2, and upper wires 211, upper vias, and upper insulation layer 212 may be formed on the gate contact pattern CB. Accordingly, an upper wire structure 210 may be formed on the upper surface of the second interlayer insulating layer 170.

According to an embodiment, the upper wire structure 210 may be connected to at least one of the first source/drain pattern SD1 and the second source/drain pattern SD2.

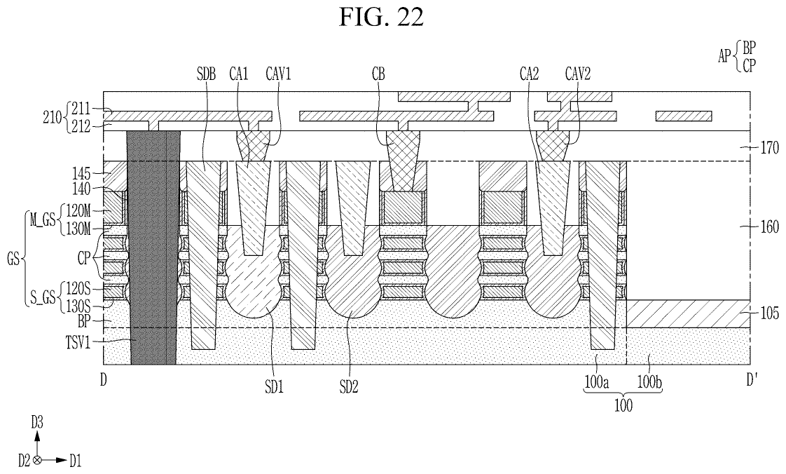

Referring to FIG. 22, the semiconductor substrate 100 may be flipped over so that the second surface of the semiconductor substrate 100 is exposed. The thickness of the semiconductor substrate 100 may be reduced by performing a planarization process on the second surface of the semiconductor substrate 100. According to an embodiment, the planarization process may be performed until the upper through via TSV1 is exposed.

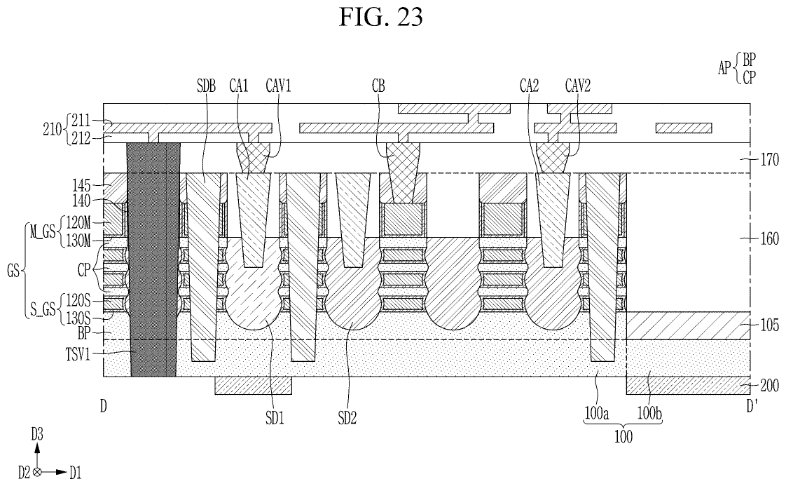

Referring to FIG. 23, a mask pattern 200 may be formed by overlapping the first source/drain pattern SD1 and the second portion 100b and the third direction D3. According to an embodiment, the mask pattern 200 may be formed to cover a portion of the first portion 100a that overlaps with the first source/drain pattern SD1 and a bottom surface of the second portion 110b.

Mask pattern 200 may be a layer to protect the first portion 100a that overlaps with the first source/drain pattern SD1 and the second portion 110b from being removed in a subsequent process. For example, mask pattern 200 may be formed of a hard mask including an oxide layer, polysilicon, or a combination thereof.

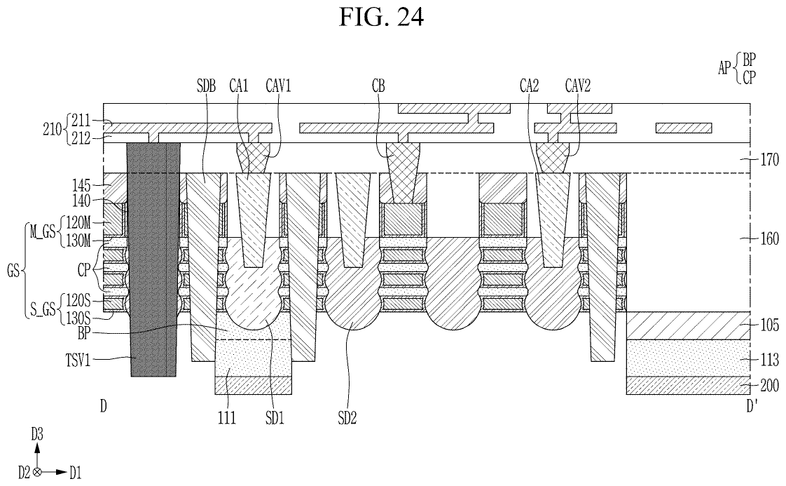

Referring to FIG. 24, the semiconductor substrate 100 and at least a portion of the lower pattern BP may be removed. At this time, since the mask pattern 200 protects the part of the first portion 100a that overlaps with the first source/drain pattern SD1, the part of the first portion 100a that overlaps with the first source/drain pattern SD1 is not removed and may remain as the first region 111. Similarly, since mask pattern 200 protects second portion 110b, second portion 110b may not be removed and remain as third region 113.

According to an embodiment, the semiconductor substrate 100, except for the first region 111 and the third region 113, may be completely removed. According to an embodiment, the semiconductor substrate 100 and the underlying pattern BP may be removed until the sub-gate structure S_GS is exposed. Specifically, the semiconductor substrate 100 and the lower pattern BP may be removed until the sub-gate structure S_GS positioned at the lowest position among the plurality of sub-gate structures S_GS is exposed.

However, it is not limited to this, and the upper part of the lower pattern BP may remain with a predetermined thickness. Accordingly, the sub-gate structure S_GS may not be exposed.

Also, although not shown, during the process of removing the semiconductor substrate 100 and the lower pattern BP, the lower part of the second source/drain pattern SD2 may be partially removed. However, this is not limited to the above, and if a passivation layer protecting the second source/drain pattern SD2 is formed, the second source/drain pattern SD2 may not be removed.

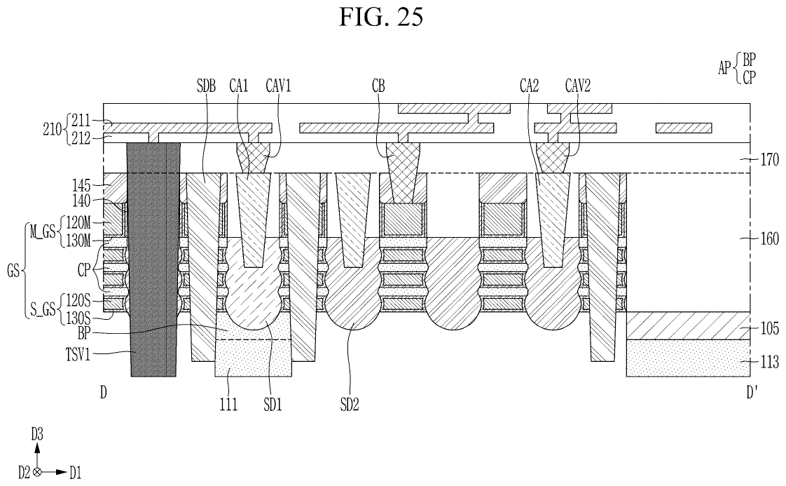

Referring to FIG. 25, the mask pattern 200 covering the first region 111 and the third region 113 may be removed. However, this is not limited to this, and mask pattern 200 may remain without being removed.

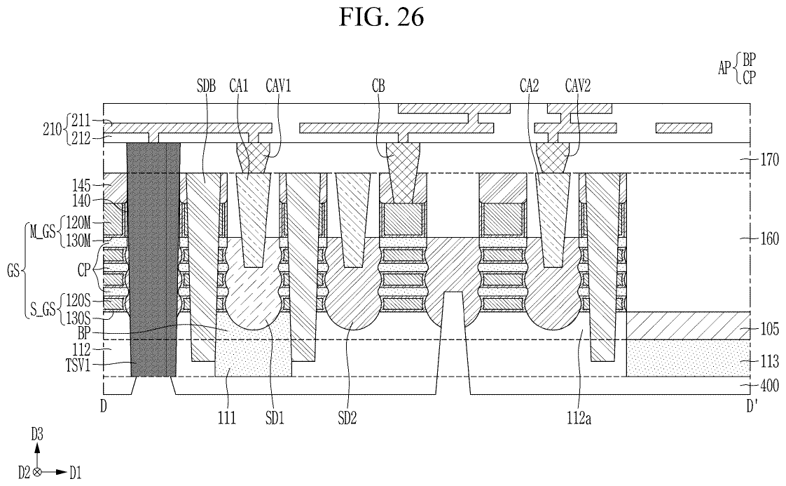

Referring to FIG. 26, the semiconductor substrate 100 and the space from which the lower pattern BP has been removed may be filled with an insulating material to form a second region 112 and a protruding region 112a.

According to an embodiment, the protruding region 112a may fill the space where the lower pattern BP is removed. According to an embodiment, the second region 112 may fill at least a portion of the space from which the first portion 100a of the semiconductor substrate 100 is removed. The second region 112 may be formed to cover the lower surface of the separating structure SDB.

According to an embodiment, the second region 112 may include an insulating material. For example, the second region 112 may include at least one of silicon oxide Si02, silicon nitride (SiN), silicon nitride (SiON), and a low dielectric constant material.

According to an embodiment, a first lower insulation layer 400 may be formed on the bottom surfaces of the first region 111, the second region 112, and the third region 113. By patterning the first lower insulation layer 400, first openings and second openings may be formed. The first opening may penetrate the first lower insulation layer 400 to expose the bottom surface of the upper through via TSV1. The second openings may penetrate the first lower insulation layer 400, the second region 112 and the protruding region 112a to expose the second source/drain pattern SD2.

Referring to FIG. 27, a through via TSV and the second source/drain pattern SD2 and a lower contact pattern BCA electrically connected to each other may be formed, and a lower wire structure 410 electrically connected to the through via TSV and the lower contact pattern BCA may be formed.

According to an embodiment, a lower through via TSV2 may be formed by filling metal within the first opening. The lower through via TSV2 may be directly connected to the upper through via TSV1 to form a through via TSV.

According to an embodiment, a lower contact pattern BCA may be formed by filling metal within the second openings. The lower contact pattern BCA may be connected to at least one of the second source/drain patterns SD2.

Next, lower wires 411, lower vias, and a second lower insulation layer 412 may be formed under the through vias TSV and lower contact patterns BCA. Accordingly, a lower wire structure 410 may be formed under the bottom surface of the first lower insulation layer 400. In the present disclosure, the bottom surface of the first lower insulation layer 400 may be referred to as the back side of the first lower insulation layer 400.

While this specification contains many specific details, these should not be construed as limitations on the scope of any invention or on the scope of what may be claimed, but rather as descriptions of features that may be specific to particular embodiments of particular inventions. Certain features that are described in this specification in the context of separate embodiments can also be in combination in a single embodiment. Conversely, various features that are described in the context of a single embodiment can also be embodied in multiple embodiments separately or in any suitable subcombination. Moreover, although features may be described above as acting in certain combinations, one or more features from a combination can in some cases be excised from the combination, and the combination may be directed to a subcombination or variation of a subcombination.

Although some embodiments have been described in detail above, the scope of the present disclosure is not limited thereto, and various modifications and improvements made by a person of an ordinary skill in the art using the basic concept of the present disclosure defined in the following claims also fall within the scope of the present disclosure.

What is claimed is:

1. A semiconductor device comprising:
a substrate including a first surface and a second surface facing each other, the substrate having a first region and a second region, the first region including conductive impurities,
a channel pattern spaced apart in a first direction on the first surface,
a first source/drain pattern on the first region,
a plurality of second source/drain patterns connected with a first side and a second side of the channel pattern, the plurality of second source/drain patterns being on the second region,
a gate structure surrounding the channel pattern and extending in a second direction, the second direction intersecting the first direction,
a separation structure extending through the gate structure on a first side and a second side of the first source/drain pattern, and
a lower wiring structure on the second surface of the substrate,
wherein a material in the first region is different from a material in the second region.

2. The semiconductor device of claim 1, wherein the first source/drain pattern includes a first conductivity type impurity and the plurality of second source/drain patterns include a second conductivity type impurity.

3. The semiconductor device of claim 2, wherein the first conductive type impurity is a p-type impurity and the second conductive type impurity is an n-type impurity, or the first conductive type impurity is an n-type impurity and the second conductive type impurity is a p-type impurity.

4. The semiconductor device of claim 1, wherein the first region includes a semiconductor material and the second region includes an insulating material.

5. The semiconductor device of claim 1, comprising a through via extending through the substrate in a third direction and connecting the lower wiring structure and the first source/drain pattern, the third direction being perpendicular to the first direction and the second direction.

6. The semiconductor device of claim 5, comprising an upper wiring structure on the first surface,
wherein the upper wiring structure is connected with at least one of the first source/drain pattern or the plurality of second source/drain patterns.

7. The semiconductor device of claim 1,
wherein the substrate comprises a cell region and a peripheral region outside the cell region, and
wherein the first region is within the peripheral region, and the second region is within the cell region.

8. The semiconductor device of claim 1,
wherein the substrate comprises a plurality of cell regions,
wherein each cell region of the plurality of cell regions includes a device region and a dummy region, and
wherein the first region is within the dummy region, and the second region is within the device region.

9. The semiconductor device of claim 1, comprising a mask pattern on a lower surface of the first region, the mask pattern comprising a material different from a material of the second region.

10. A semiconductor device comprising:
a substrate including a first surface and a second surface facing each other, the substrate having a first region and a second region, the first region including conductive impurities,
a lower pattern extending in a first direction on the first surface,
a plurality of channel patterns stacked and spaced apart from each other on the lower pattern,
a first source/drain pattern on the first region,
a plurality of second source/drain patterns connected with a first side and a second side of the channel pattern, the plurality of second source/drain patterns being on the second region,
a gate structure extending in a second direction intersecting the first direction and surrounding the channel pattern,
a separation structure extending through the gate structure on a first side and a second side of the first source/drain pattern, and
a lower wiring structure on the second surface of the substrate,
wherein a material in the first region is different from a material in the second region.

11. The semiconductor device of claim 10, wherein the first source/drain pattern includes a first conductivity type impurity and the plurality of second source/drain patterns include a second conductivity type impurity.

12. The semiconductor device of claim 11, wherein the first conductive type impurity is a p-type impurity and the second conductive type impurity is an n-type impurity, or the first conductive type impurity is an n-type impurity and the second conductive type impurity is a p-type impurity.

13. The semiconductor device of claim 10, wherein the first region includes a semiconductor material and the second region includes an insulating material.

14. The semiconductor device of claim 10, comprising a through via extending through the substrate in a third direction and connecting the lower wiring structure and the first source/drain pattern, the third direction being perpendicular to the first direction and the second direction.

15. The semiconductor device of claim 14, comprising an upper wiring structure on the first surface,
wherein the upper wiring structure is connected with at least one of the first source/drain pattern and the plurality of second source/drain patterns.

16. The semiconductor device of claim 10,
wherein the substrate comprises a cell region and a peripheral region positioned outside the cell region, and
wherein the first region is within the peripheral region and the second region is positioned within the cell region.

17. The semiconductor device of claim 10,
wherein the substrate comprises a plurality of cell regions,
wherein each cell region of the plurality of cell regions includes a device region and a dummy region, and
wherein the first region is within the dummy region, and the second region is within the device region.

18. The semiconductor device of claim 10, comprising a mask pattern on a lower surface of the first region, the mask pattern comprising a material different from a material of the second region.

19. A semiconductor device comprising:
a substrate comprising a first surface and a second surface facing each other, a first region including conductive impurities, a second region including an insulating material, and a third region,
a channel pattern spaced apart in a first direction on the first surface of the substrate,
a first source/drain pattern on the first region,
a plurality of second source/drain patterns connected with a first side and a second side of the channel pattern, the plurality of second source/drain patterns being on the second region,
a gate structure extending in a second direction intersecting the first direction and surrounding the channel pattern,
a separation structure extending through the gate structure on a first side and a second side of the first source/drain pattern, and
a lower wiring structure on the second surface of the substrate,
wherein the first region and the third region include a same material, and a material in the first region is different from a material in the second region.

20. The semiconductor device of claim 19, wherein the first region and the third region include semiconductor materials.
